(19) United States
(12) Patent Application Publication
(10) Pub. No.: US 2026/0236391 A1
(43) Pub. Date: Aug. 13, 2026

(54) MEMORY SYSTEMS, METHODS OF OPERATING THEREOF, MEMORY CONTROLLERS AND STORAGE MEDIUMS

(71) Applicant: Yangtze Memory Technologies Co., Ltd., Wuhan (CN)

(72) Inventors: Zhi Zhang, Wuhan (CN); Yan Tao, Wuhan (CN); Ling Shi, Wuhan (CN)

(21) Appl. No.: 19/065,779

(22) Filed: Feb. 27, 2025

(30) Foreign Application Priority Data
Feb. 12, 2025 (CN) 202510157333.3

(51) Int. Cl. G06F 12/02

(52) U.S. Cl. CPC G06F 12/0246; G06F 2212/7202

(57) ABSTRACT

According to one aspect, a method of operating a memory system is provided. The method may include: performing a redundant array coding operation on received user data to generate check data; allocating a first physical address for storing the user data, where the first physical address points to a first memory region of a plurality of memory regions; allocating and recording a second physical address for storing the check data, where the second physical address points to a second memory region; sending a first writing instruction including the first physical address to the memory device, where the first writing instruction may indicate to write the user data into the first memory region; sending a second writing instruction that includes the second physical address and is different from the first writing instruction to the memory device to write the check data into the second memory region.

### CROSS-REFERENCE TO RELATED APPLICATIONS

This application claims the benefit of priority to Chinese Application No. 202510157333.3, filed on Feb. 12, 2025, which is incorporated herein by reference in its entirety.

### FIELD

Embodiments of the present application relate to, but are not limited to, the field of integrated circuits, e.g., to a memory system, an operation method thereof, a memory controller, and a storage medium.

### BACKGROUND

Memory devices are storage devices in modern information technology for storing information. As a typical non-volatile semiconductor memory, NAND (Not-And) type memories gradually become mainstream products in the storage market due to their high memory density, controllable production cost, and suitable erasing speed. However, with the increasing demand for storage devices, there is still significant room for improvement in memory devices and their systems

### SUMMARY

According to one aspect of the present disclosure, a memory system is provided. The memory system may include a memory controller and a memory device coupled to the memory controller. The memory device may include a plurality of memory regions. The memory controller may be configured to perform a redundant array coding operation on the received user data to generate check data. The memory controller may be configured to allocate a first physical address for storing the user data. The first physical address may point to a first memory region of the plurality of memory regions. The memory controller may be configured to allocate a second physical address for storing the check data, and recording the second physical address. The second physical address may point to a second memory region of the plurality of memory regions that is different from the first memory region. The memory controller may be configured to send a first writing instruction including the first physical address to the memory device. The first writing instruction may indicate to write the user data into the first memory region. The memory controller may be configured to send a second writing instruction that includes the second physical address and is different from the first writing instruction to the memory device. The second writing instruction may indicate to write the check data into the second memory region.

In some implementations, the first memory region may include a plurality of first dies, and the first die may include a plurality of first memory blocks. In some implementations, a plurality of the first memory blocks in different first dies may form a superblock. In some implementations, the memory controller may be configured to allocate the first physical address based on the plurality of managed superblocks. In some implementations, the first physical address points to a target superblock in a plurality of superblocks.

In some implementations, the second memory region may include at least one second die, and the second die may include a plurality of second memory blocks. In some implementations, the memory controller may be configured to allocate the second physical address based on a plurality of managed second memory blocks. In some implementations, the second physical address may point to a target second memory block in the plurality of the second memory blocks.

In some implementations, the memory controller may be configured to manage a plurality of the superblocks and a plurality of the second memory blocks.

In some implementations, the memory controller may be configured to obtain a first metadata related to the user data from the memory device. In some implementations, the first metadata may include index information related to the check data. In some implementations, the memory controller may be configured to retrieve a mapping table based on the index information to determine the second physical address for storing the check data. In some implementations, the mapping table may include a mapping relationship between the index information and the second physical address.

In some implementations, the mapping table may include a plurality of entries, and one of the entries may record the second physical address corresponding to one piece of the index information. In some implementations, the memory controller may be configured to retrieve the mapping table based on the index information to determine a target entry in the plurality of entries. In some implementations, the memory controller may be configured to determine the second physical address for storing the check data based on the target entry.

In some implementations, the superblock may include at least one stripe, the first physical address may point to a target stripe in a plurality of stripes of the target superblock, and the target stripe may be configured to store the user data. In some implementations, the memory controller may be configured to determine a corresponding second identifier in the index information based on a first identifier in the index information. In some implementations, the first identifier may be configured to indicate a position of the target stripe, and the second identifier may be configured to indicate a position of the target entry. In some implementations, the memory controller may be configured to obtain the target entry based on the second identifier.

In some implementations, the memory controller may be configured to allocate a blank entry of the plurality of entries, and record the second physical address into the blank entry.

In some implementations, the memory controller may be configured to obtain second metadata related to the check data from the memory device. In some implementations, the second metadata may include address information related to the user data. In some implementations, the memory controller may be configured to determine that an error occurs in the second physical address recorded in the target entry based on the address information in the second metadata does not match the first physical address. In some implementations, the memory controller may be configured to reconstruct the target entry based on an error that occurs in the second physical address recorded in the target entry.

In some implementations, the memory controller may be configured to determine that the second physical address recorded in the target entry is correct based on the address information in the second metadata matches the first physical address.

In some implementations, the address information in the second metadata may include a start bit for storing a physical address of the user data and an end bit for storing a physical address of the user data.

In some implementations, a memory cell of the first memory region and a memory cell of the second memory region may be respectively configured in different storage modes.

In some implementations, the memory cell in the first memory region may be configured to store M-bit data. In some implementations, the memory cell in the second memory region may be configured to store N-bit data. In some implementations, both M and N may be integers greater than 1. In some implementations, N may be less than M.

In some implementations, the memory controller may be further configured to obtain the user data stored in the first memory region from the memory device. In some implementations, the memory controller may be further configured to send a reading instruction including the second physical address to the memory device based on an error-correcting code check performed on the obtained user data fails. In some implementations, the reading instruction may indicate to read the check data stored in the second memory region. In some implementations, the memory controller may be further configured to perform a redundant array check on the user data by using the read check data.

In some implementations, the memory system may include a solid state disk, a universal flash memory, or an embedded multimedia card.

According to another aspect of the present disclosure, a memory system is provided. The memory system may include a memory controller and a memory device coupled to the memory controller. The memory device may include a plurality of dies divided into a plurality of memory regions. The memory controller may be configured to migrate a partial user data stored in a faulty memory block in a first memory region to a target memory block in the first memory region based on at least one faulty memory block exists in a first memory region of the plurality of memory regions. The memory controller may be configured to update a first physical address for storing the user data, based on the partial user data migrated to the target memory block in the first memory region. The first physical address may point to the first memory region. The memory controller may be configured to re-performing a redundant array coding operation on the partial user data migrated to the target memory block in the first memory region and remaining user data that is not migrated in the first memory region to generate first check data. The memory controller may be configured to allocate a third physical address for storing the first check data, and record the third physical address. The third physical address may point to a second memory region of the plurality of memory regions that is different from the first memory region. The memory controller may be configured to send a third writing instruction including the third physical address to the memory device. The third writing instruction may indicate to write the first check data into the second memory region.

In some implementations, the memory controller may be further configured to re-perform the redundant array coding operation on the user data stored in the first memory region based on the at least one faulty memory block exists in the second memory region to generate second check data. In some implementations, the memory controller may be further configured to allocate a fourth physical address for storing the second check data, and record the fourth physical address. In some implementations, the fourth physical address may point to a target memory block in the second memory region. In some implementations, the memory controller may be further configured to send a fourth writing instruction including the fourth physical address to the memory device. In some implementations, the fourth writing instruction may indicate to write the second check data into a target memory block in the second memory region.

In some implementations, the first memory region may include a plurality of first dies, the first die may include a plurality of first memory blocks. In some implementations, a plurality of first memory blocks in different first dies may form a superblock. In some implementations, the memory controller may be configured to allocate the first physical address based on the plurality of managed superblocks. In some implementations, the first physical address may point to a target superblock in a plurality of superblocks.

In some implementations, the second memory region may include at least one second die, and the second die may include a plurality of second memory blocks. In some implementations, the memory controller may be further configured to allocate the fourth physical address based on the plurality of managed second memory blocks. In some implementations, the fourth physical address may point to a target second memory block in the target second die.

In some implementations, the memory controller may be further configured to manage a plurality of the superblocks and a plurality of the second memory blocks.

In some implementations, the memory controller may be further configured to obtain a third metadata related to the user data from the memory device. In some implementations, the third metadata may include index information related to the first check data. In some implementations, the memory controller may be further configured to retrieve a mapping table based on the index information to determine the third physical address for storing the first check data. In some implementations, the mapping table may include a mapping relationship between the index information and the third physical address.

In some implementations, the mapping table may include a plurality of entries, and one entry may record the third physical address corresponding to one piece of the index information. In some implementations, the memory controller may be further configured to retrieve the mapping table based on the index information to determine a target entry in the plurality of entries. In some implementations, the memory controller may be further configured to determine the third physical address for storing the first check data based on the target entry.

In some implementations, the superblock may include at least one stripe, the updated first physical address may point to a target stripe in a plurality of stripes of the target superblock, and the target stripe may be configured to store the user data. In some implementations, the memory controller may be further configured to determine a corresponding second identifier in the index information based on a first identifier in the index information. In some implementations, the first identifier may be configured to indicate a position of the target stripe, and the second identifier may be configured to indicate a position of the target entry. In some implementations, the memory controller may be further configured to obtain the target entry based on the second identifier.

In some implementations, the memory controller may be further configured to allocate a blank entry of the plurality of entries. In some implementations, the memory controller may be further configured to record the third physical address into the blank entry.

In some implementations, the memory controller may be further configured to obtain a fourth metadata related to the first check data from the memory device. In some implementations, the fourth metadata may include address information related to the user data. In some implementations, the memory controller may be further configured to determine that an error occurs in the third physical address recorded in the target entry based on the address information in the fourth metadata does not match the updated first physical address. In some implementations, the memory controller may be further configured to reconstruct the target entry based on an error that occurs in the third physical address recorded in the target entry.

In some implementations, the memory controller may be further configured to determine that the third physical address recorded in the target entry is correct based on the address information in the fourth metadata matches a new first physical address.

In some implementations, the address information in the fourth metadata may include a start bit for storing a physical address of the user data and an end bit for storing a physical address of the user data.

In some implementations, a memory cell of the first memory region and a memory cell of the second memory region may be respectively configured in different storage modes.

In some implementations, the memory cell in the first memory region may be configured to store M-bit data. In some implementations, the memory cell in the second memory region may be configured to store N-bit data. In some implementations, both M and N may be integers greater than 1. In some implementations, N may be less than M.

In some implementations, the memory controller may be further configured to determine a memory region in which the faulty memory block is located, based on the at least one memory block exists in the plurality of dies.

In some implementations, the memory controller may be further configured to determine that at least one dies is a faulty die, based on a number of faulty memory blocks within the at least one of the plurality of dies being greater than a preset threshold.

In some implementations, the memory controller may be further configured to obtain the user data stored in the first memory region from the memory device. In some implementations, the memory controller may be further configured to send a reading instruction including the third physical address to the memory device based on an error-correcting code check performed on the obtained user data fails. In some implementations, the reading instruction may indicate to read the first check data stored in the second memory region. In some implementations, the memory controller may be further configured to perform a redundant array check on the user data using the read first check data.

In some implementations, the memory system may include a solid state disk, a universal flash memory, or an embedded multimedia card.

According to a further aspect of the present disclosure, a memory controller is provided. The memory controller may include a cache and a processor. The processor may be configured to perform a redundant array coding operation on the received user data to generate check data. The processor may be configured to allocate a first physical address for storing the user data. The first physical address may point to a first memory region of a plurality of memory regions of a memory device. The processor may be configured to allocate a second physical address for storing the check data, and record the second physical address. The second physical address may point to a second memory region of the plurality of memory regions of the memory device that is different from the first memory region. The processor may be configured to send a first writing instruction including the first physical address to the memory device. The first writing instruction may indicate to write the user data into the first memory region. The processor may be configured to send a second writing instruction that includes the second physical address and is different from the first writing instruction to the memory device. The second writing instruction may indicate to write the check data into the second memory region.

In some implementations, the first memory region may include a plurality of first dies. In some implementations, the first die may include a plurality of first memory blocks. In some implementations, a plurality of the first memory blocks in different first dies may form a superblock. In some implementations, the processor is configured to allocate the first physical address based on the plurality of managed superblocks. In some implementations, the first physical address may point to a target superblock in a plurality of the superblocks.

In some implementations, the second memory region may include at least one second die, and the second die may include a plurality of second memory blocks. In some implementations, the processor is further configured to allocate the second physical address based on the plurality of managed second memory blocks. In some implementations, the second physical address may point to a target second memory block of the plurality of second memory blocks.

In some implementations, the processor may be configured to manage a plurality of the superblocks and the plurality of second memory blocks.

In some implementations, the processor may be configured to obtain a first metadata related to the user data from the memory device. In some implementations, the first metadata may include index information related to the check data. In some implementations, the processor may be configured to retrieve a mapping table based on the index information to determine the second physical address for storing the check data. In some implementations, the mapping table may include a mapping relationship between the index information and the second physical address.

In some implementations, the mapping table may include a plurality of entries, and one of the entries may record the second physical address corresponding to one piece of the index information. In some implementations, the processor may be configured to retrieve the mapping table based on the index information to determine a target entry in the plurality of entries. In some implementations, the processor may be configured to determine the second physical address for storing the check data based on the target entry.

In some implementations, the superblock may include at least one stripe, the first physical address may point to a target stripe in a plurality of stripes of the target superblock, and the target stripe may be configured to store the user data. In some implementations, the processor may be configured to determine a corresponding second identifier in the index information based on a first identifier in the index information. In some implementations, the first identifier may be configured to indicate a position of the target stripe, and the second identifier may be configured to indicate a position of the target entry. In some implementations, the processor may be configured to obtain the target entry based on the second identifier.

In some implementations, the processor may be configured to allocate a blank entry of the plurality of entries, and record the second physical address into the blank entry.

In some implementations, the processor may be configured to obtain a second metadata related to the check data from the memory device. In some implementations, the second metadata may include address information related to the user data. In some implementations, the processor may be configured to determine that an error occurs in the second physical address recorded in the target entry based on the address information in the second metadata does not match the first physical address. In some implementations, the processor may be configured to reconstruct the target entry based on an error that occurs in the second physical address recorded in the target entry.

In some implementations, the processor may be configured to determine that the second physical address recorded in the target entry is correct based on the address information in the second metadata matches the first physical address.

In some implementations, the address information in the second metadata may include a start bit for storing a physical address of the user data and an end bit for storing a physical address of the user data.

In some implementations, a memory cell of the first memory region and a memory cell of the second memory region may be respectively configured in different storage modes.

In some implementations, the memory cell in the first memory region may be configured to store M-bit data. In some implementations, the memory cell in the second memory region may be configured to store N-bit data. In some implementations, both M and N may be integers greater than 1. In some implementations, N may be less than M.

In some implementations, the processor may be further configured to obtain the user data stored in the first memory region from the memory device. In some implementations, the processor may be further configured to send a reading instruction including the second physical address to the memory device based on an error-correcting code check performed on the obtained user data fails. In some implementations, the reading instruction may indicate to read the check data stored in the second memory region. In some implementations, the processor may be further configured to perform a redundant array check on the user data by using the read check data.

According to still another aspect of the present disclosure, a method of operating a memory system is provided. The method may include performing a redundant array coding operation on the received user data to generate check data. The method may include allocating a first physical address for storing the user data. The first physical address points to a first memory region of a plurality of memory regions of a memory device in the memory system. The method may include allocating a second physical address for storing the check data, and recording the second physical address. The second physical address may point to a second memory region of the plurality of memory regions that is different from the first memory region. The method may include sending a first writing instruction including the first physical address to the memory device. The first writing instruction may indicate to write the user data into the first memory region. The method may include sending a second writing instruction that includes the second physical address and is different from the first writing instruction to the memory device. The second writing instruction may indicate to write the check data into the second memory region.

In some implementations, the first memory region may include a plurality of first dies, and the first die may include a plurality of first memory blocks. In some implementations, a plurality of first memory blocks in different first dies form a superblock. In some implementations, the allocating a first physical address for storing the user data may include allocating the first physical address based on the plurality of managed superblocks. In some implementations, the first physical address may point to a target superblock in a plurality of superblocks.

In some implementations, the second memory region may include at least one second die, and the second die may include a plurality of second memory blocks. In some implementations, the allocating a second physical address for storing the check data may include allocating the second physical address based on a plurality of managed second memory blocks. In some implementations, the second physical address may point to a target second memory block in a plurality of second memory blocks.

In some implementations, the method may further include obtaining first metadata related to the user data from the memory device. In some implementations, the first metadata may include index information related to the check data. In some implementations, the method may further include retrieving a mapping table based on the index information to determine the second physical address for storing the check data. In some implementations, the mapping table may include a mapping relationship between the index information and the second physical address.

In some implementations, the mapping table may include a plurality of entries, and one of the entries may record the second physical address corresponding to one piece of the index information. In some implementations, the method may further include the retrieving the mapping table based on the index information to determine the second physical address for storing the check data may include retrieving the mapping table based on the index information to determine a target entry in the plurality of entries. In some implementations, the method may further include the retrieving the mapping table based on the index information to determine the second physical address for storing the check data may include determining the second physical address for storing the check data based on the target entry.

In some implementations, the superblock may include at least one stripe, the first physical address may points to a target stripe in a plurality of stripes of the target superblock, and the target stripe may be configured to store the user data. In some implementations, the retrieving the mapping table based on the index information to determine a target entry in the plurality of entries may include determining a corresponding second identifier in the index information based on a first identifier in the index information. In some implementations, the first identifier may be configured to indicate a position of the target stripe, and the second identifier may be configured to indicate a position of the target entry. In some implementations, the retrieving the mapping table based on the index information to determine a target entry in the plurality of entries may include obtaining the target entry based on the second identifier.

In some implementations, the recording the second physical address may include allocating a blank entry of the plurality of entries. In some implementations, the recording the second physical address may include recording the second physical address into the blank entry.

In some implementations, the method may further include obtaining a second metadata related to the check data from the memory device. In some implementations, the second metadata may include address information related to the user data. In some implementations, the method may further include determining that an error occurs in the second physical address recorded in the target entry based on the address information in the second metadata does not match the first physical address. In some implementations, the method may further include reconstructing the target entry based on an error that occurs in the second physical address recorded in the target entry.

In some implementations, the method may further include determining that the second physical address recorded in the target entry is correct based on the address information in the second metadata matches the first physical address.

In some implementations, the address information in the second metadata may include a start bit for storing a physical address of the user data and an end bit for storing a physical address of the user data.

In some implementations, a memory cell in the first memory region may be configured to store M-bit data. In some implementations, a memory cell in the second memory region may be configured to store N-bit data. In some implementations, both M and N may be integers greater than 1. In some implementations, N may be less than M.

In some implementations, the method may further include obtaining the user data stored in the first memory region from the memory device. In some implementations, the method may further include sending a reading instruction including the second physical address to the memory device based on an error-correcting code check performed on the obtained user data fails. In some implementations, the reading instruction may indicate to read the check data stored in the second memory region. In some implementations, the method may further include performing a redundant array check on the user data by using the read check data.

According to still a further aspect of the present disclosure, a non-transitory computer-readable medium storing instructions is provided. The instructions, which when executed by a processor of a memory system, cause the processor of the memory system to perform operations. The operations may include performing a redundant array coding operation on the received user data to generate check data. The operations may include allocating a first physical address for storing the user data. The first physical address points to a first memory region of a plurality of memory regions of a memory device in the memory system. The operations may include allocating a second physical address for storing the check data, and record the second physical address. The second physical address may point to a second memory region of the plurality of memory regions that is different from the first memory region. The operations may include sending a first writing instruction including the first physical address to the memory device. The first writing instruction indicates to write the user data into the first memory region. The operations may include sending a second writing instruction that including the second physical address and is different from the first writing instruction to the memory device. The second writing instruction may indicate to write the check data into the second memory region.

In the implementations of the present application, a redundant array coding operation is performed on the received user data to generate corresponding check data. The first physical address and the second physical address are allocated to the user data and the check data respectively. In some implementations, the first physical address points to a first memory region of the plurality of memory regions, and the second physical address points to a second memory region of the plurality of memory regions that is different from the first memory region. A first writing instruction including the first physical address and a second writing instruction including the second physical address are sent to store the user data and the check data to the first memory region and the second memory region respectively. On one hand, the implementations of the present application realize independent management of user data and check data by storing user data and check data separately, and improve the performance and flexibility of the memory system. In addition, it provides conditions for quickly locating to the location of the check data by recording the second physical address, thereby improving the fault-tolerant capability and the data recovery speed of the memory system. On the other hand, independent writing of user data and check data is implemented via different writing instructions, and the first writing instruction and the second writing instruction independent of each other can further be processed in parallel, further improving data writing efficiency. In addition, the risk of simultaneous loss of user data and check data is reduced.

### BRIEF DESCRIPTION OF DRAWINGS

In the figures, like reference numbers refer to like or similar parts or elements throughout several figures unless otherwise specified. These figures are not necessarily drawn to scale. It should be understood that these figures depict only some implementations disclosed in accordance with the present application and should not be construed as limiting the scope of the present application.

FIG. 1 is a first schematic diagram of an example system having a memory system according to an implementation of the present application;

FIG. 2 is a schematic diagram of an example memory card having a memory system according to an implementation of the present application;

FIG. 3 is a schematic diagram of an example solid state driver having a memory system according to an implementation of the present application;

FIG. 4 is a schematic diagram of an example memory device including a peripheral circuit according to an implementation of the present disclosure;

FIG. 5 is a schematic diagram of an example memory including a memory cell array and a peripheral circuit according to an implementation of the present application;

FIG. 6 is a second schematic diagram of an example system having a memory system according to an implementation of the present application.

FIG. 7 is a schematic diagram of a die, a memory block, a superblock, and a stripe in a memory device according to an implementation of the present application;

FIG. 8 is a schematic diagram of a storage plane, a memory block, and a superblock in a memory device according to an implementation of the present application;

FIG. 9 is a schematic diagram of a channel layout between a memory controller and a memory device according to an implementation of the present application;

FIG. 10 is a schematic diagram of a principle of a RAID 5 according to an implementation of the present application;

FIG. 11 is a first timing diagram of performing a writing operation according to an implementation of the present application;

FIG. 12 is a second timing diagram of performing a writing operation according to an implementation of the present application;

FIG. 13 is a first schematic diagram of a first memory region and a second memory region;

FIG. 14 is a second schematic diagram of a first memory region and a second memory region;

FIG. 15 is a schematic diagram of a relationship between user data stored in one superblock and check data stored in a second memory block shown in FIG. 14;

FIG. 16 is a schematic diagram of a relationship between index information and a mapping table according to an implementation of the present application;

FIG. 17A is a first flowchart of a method of operating a memory system according to an implementation of the present application;

FIG. 17B is a second flowchart of a method of operating a memory system according to an implementation of the present application;

FIG. 18 is a first process diagram of a method of operating a memory system according to an implementation of the present application;

FIG. 19 is a second process diagram of a method of operating a memory system according to an implementation of the present application;

FIG. 20 is a third flowchart of a method of operating a memory system according to an implementation of the present application;

FIG. 21A is a first flowchart of data writing according to an implementation of the present application;

FIG. 21B is a second flowchart of data writing according to an implementation of the present application;

FIG. 22 is a schematic diagram of a data reading process according to an implementation of the present application;

FIG. 23 is a block diagram of a storage medium according to an implementation of the present application.

### DETAILED DESCRIPTION

Example implementations disclosed in the present disclosure will be described in more detail below with reference to the drawings. Although example implementations of the present disclosure are illustrated in the drawings, it should be understood that the present disclosure may be implemented in various manners and should not be limited to the implementations set forth herein. Rather, these implementations are provided so that the present disclosure may be understood more thoroughly and the scope of the present disclosure may be fully presented to those skilled in the art.

Numerous details are introduced hereinafter in order to provide a more thorough understanding of the present disclosure. However, it would be obvious to one skilled in the art that, the present disclosure may be practiced without one or more of these details. In other examples, in order to avoid a confusion with the present disclosure, some technical features known in the art are not described; that is, not all the features of the actual implementations are described herein, and well-known functions and structures are not described in detail.

In addition, the figures are merely schematic illustrations of the present application, and are not necessarily drawn to scale. Like reference numerals in the figures refer to the same or similar parts, and repeated description thereof will be omitted. Some of the block diagrams shown in the figures are functional entities and do not necessarily have to correspond to physically or logically separate entities. These functional entities may be implemented in software form, or implemented in one or more hardware modules or integrated circuits, or implemented in different networks and/or processor devices and/or microcontroller devices.

The flowchart shown in the figures is merely exemplary and not necessarily all steps. For example, the steps may be further decomposed, and some steps may be combined or partially combined, so the actual execution sequence may be changed according to actual conditions.

A term used herein is merely for the purpose of describing an implementation and is not limiting the present disclosure. As used herein, unless the context indicates otherwise clearly, the singular form of “a”, “an” and “said/the” are intended to comprise the plural form as well. It should further be understood that the terms of “including” and/or “comprising”, when used in the description, indicates a presence of the stated features, integers, steps, operations, elements and/or components, rather than exclude a presence of one or more other features, integers, steps, operations, elements, components and/or groups. As used herein, term “and/or” comprises any and all combinations of the related listed items.

The memory device in the implementations of the present application includes, but is not limited to, a three-dimensional NAND type memory, and to facilitate the understanding, taking the three-dimensional NAND type memory as an example for description.

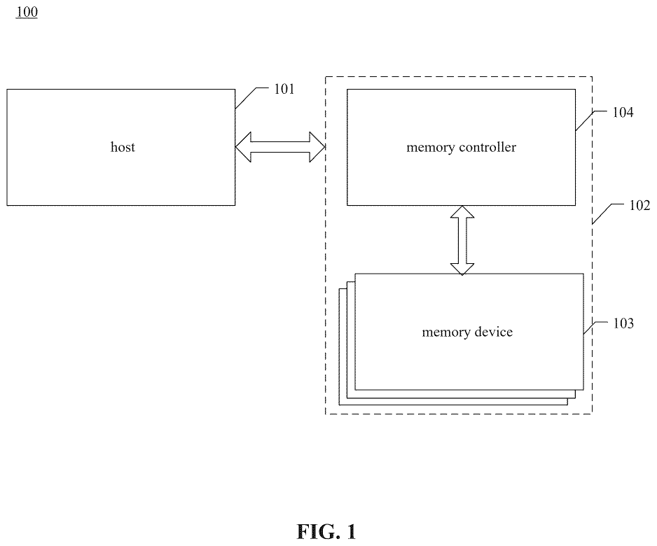

FIG. 1 is a schematic diagram of an example system having a memory system according to an implementation of the present disclosure. In some examples, the system 100 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory therein. As shown in FIG. 1, the system 100 may include a host 101 and a memory system 102, the memory system 102 may include one or more memory devices 103 and a memory controller 104. The host 101 may include a processor of an electronic device, for example, a Central Processing Unit (CPU), or a System on a Chip (SoC), such as an application processor (AP). The host 101 may be configured to transmit data to or receive data from the memory system 102.

In some examples, the memory controller 104 is coupled to the memory device 103 and the host 101, and is configured to control the memory device 103. The memory controller 104 may manage data stored in the memory device 103 and communicate with the host 101. In some examples, the memory controller 104 is designed to operate in a low duty cycle environment, such as in a secure digital card, Compact Flash Card (CFC), Universal Serial Bus (USB) flash driver, or to operate in other medium for use in electronic device such as personal computer, digital camera, mobile phone, and the like. In further examples, the memory controller 104 is designed to operate in a high duty cycle environment, such as in a solid state disk or embedded Multi-Media Card (eMMC).

In some implementations, the memory controller 104 is configured to manage the mapping of data stored in the memory device 103, and in an example, the memory controller 104 may update and maintain a L2P table, and each mapping entry in the L2P table may represent a mapping relationship between a logical address and a physical address. When the host 101 sends a read request including a logical address to the memory controller 104, the memory controller 104 may obtain a corresponding physical address based on the logical address in the L2P table and the read request, and read data from the memory device 103 according to the physical address and send to the host 101.

In some examples, the memory controller 104 and the one or more memory devices 103 may be integrated into various types of storage devices, that is, the memory system 102 may be implemented and packaged into different types of terminal electronic products.

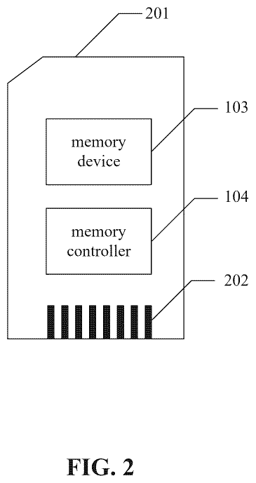

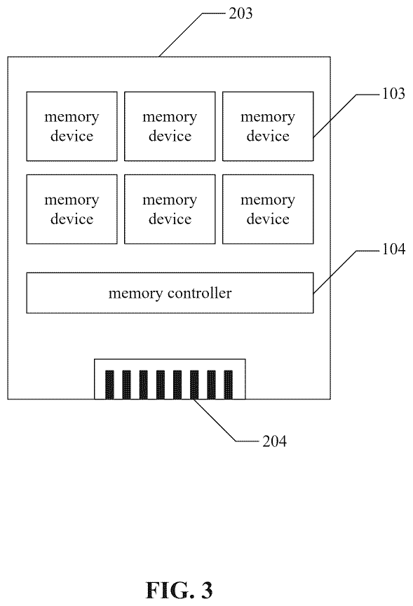

In one example as shown in FIG. 2, the memory controller 104 and a single memory device 103 may be integrated into a memory card 201. The memory card 201 may be one of a compact flash memory card, a Smart Media Card (SMC), a Memory Stick (MS), a Multi-Media Card (MMC) (e.g., reduced-size (RS)-MMC, MMCmicro, eMMC or the like), a secure digital (SD) card (e.g., Mini SD card, Micro SD card, SD high capacity (HC) (SDHC) card or the like), and a universal flash memory card. The memory card 201 may further include a memory card connector 202 that couples the memory card 201 with a host-side device (e.g., host 101 in FIG. 1). In another example as shown in FIG. 3, the memory controller 104 and a plurality of memory devices 103 may be integrated into SSD 203. The SSD 203 may further include an SSD connector 204 that couples SSD 203 with a host-side device (e.g., host 101 in FIG. 1). In some examples, the storage capacity and/or operating speed of SSD 203 is greater than the storage capacity and/or operating speed of the memory card 201.

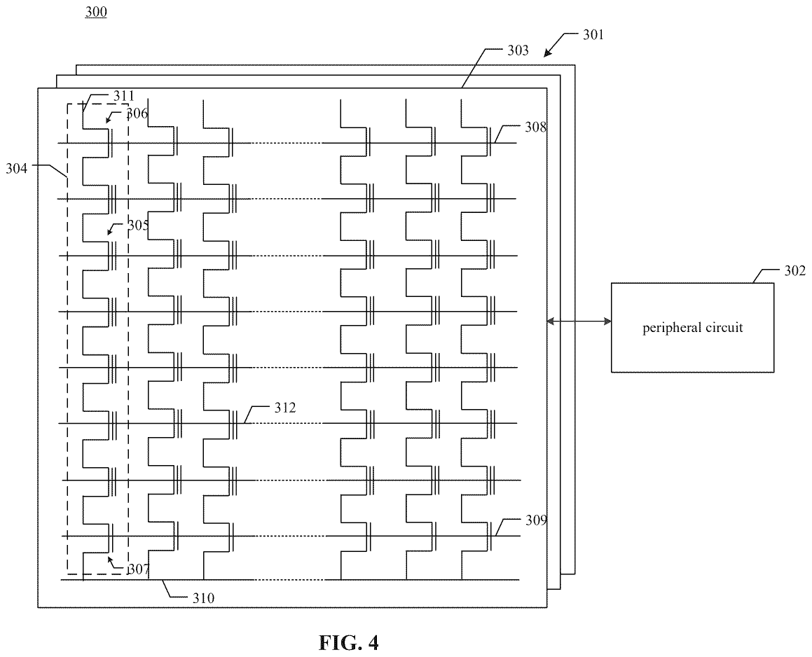

FIG. 4 is a schematic circuit diagram of an example memory device 300 including a peripheral circuit according to an implementation of the present disclosure. The memory device 300 may be an example of the memory device 103 in FIG. 1. The memory device 300 may include a memory cell array 301 and a peripheral circuit 302 coupled to the memory cell array 301. Taking the memory cell array 301 of a 3D NAND memory cell array as an example for description, where a memory cell 305 is a NAND memory cell, the memory cell 305 is provided in the form of an array of memory cell strings 304, each memory cell string 304 extends vertically above a substrate (not shown).

In some examples, each memory cell string 304 includes a plurality of memory cells 305 coupled in series and stacked vertically. Each memory cell 305 may maintain a continuous analog value, e.g., voltage or charge, which depends on the number of electrons trapped within the region of the memory cell 305. Each memory cell 305 may be a memory cell of floating gate type which includes a floating gate transistor or a memory cell of charge trap type which includes a charge trap transistor.

In some examples, each memory cell 305 is a Single Level Cell (SLC), having two possible memory states and thus may store one bit of data. For example, a first memory state “0” may correspond to a first voltage range and a second memory state “1” may correspond to a second voltage range. In some examples, each memory cell 305 is a multi-level cell, which is capable of storing more than a single bit of data in four or more memory states, e.g., a Multi-Level Cell (MLC) storing two bits per cell, a Triple Level Cell (TLC) storing three bits per cell, or a Quad-Level Cell (QLC) storing four bits per cell, or a Penta-Level Cell (PLC) that stores five bits per cell.

As shown in FIG. 4, each memory cell string 304 may include a Bottom Select Transistor (BST) 307 at its source end and a Top Select Transistor (TST) 306 at its drain end. The bottom select transistor 307 and the top select transistor 306 may be configured to activate a selected memory cell string 304 during read and program operations. In some examples, sources of the memory cell strings 304 in a same memory block 303 may be coupled through a Common Source Line (CSL) 310. In other words, all the memory cell strings 304 in the same memory block 303 have a common source (ACS).

According to some examples, a top select transistor 306 of each memory cell string 304 is coupled to a respective Bit Line (BL) 311, data may be read or written via an output bus (not shown) from the bit line 311.

In some examples, each memory cell string 304 is configured to be selected or deselected by applying a select voltage (e.g., a voltage higher than a threshold voltage of the top select transistor 306) or a deselect voltage (e.g., 0V) to a Top Select Gate (TSG) of a respective top select transistor 306 through one or more Top Select Lines (TSL) 308 and/or by applying a select voltage (e.g., a voltage higher than a threshold voltage of the bottom select transistor 307) or a deselect voltage (e.g., 0V) to a Bottom Select Gate (BSG) of a respective bottom select transistor 307 through one or more Bottom Select Lines (BSL) 309.

As shown in FIG. 4, the memory cell string 304 may be organized into a plurality of memory blocks 303, each of the memory blocks 303 may have a common source line 310. In some examples, each memory block 303 is a basic data unit for an erase operation, e.g., all the memory cells 305 on a same memory block 303 may be erased simultaneously.

To erase the memory cells 305 in a selected memory block, a common source line 310 coupled to the selected memory block and an unselected memory block(s) in the same plane as the selected memory block may be biased with an erase voltage. It should be understood that, in some examples, an erase operation may be performed at a half-memory block level, at a quarter-memory block level, or at a level with any suitable number of memory blocks or any suitable fraction of a memory block. Memory cells 305 of adjacent memory cell strings 304 may be coupled by a word line 312, the word line 312 selects which row of memory cells 305 are affected by read or program operations.

In some examples, the peripheral circuit 302 may include any suitable analog, digital, and mixed-signal circuit to enable an operation on the memory cell array 301 by applying at least one of a voltage signal or a current signal to each target memory cell 305 and sensing at least one of a voltage signal or a current signal from each target memory cell 305 through the bit line 311, the word line 312, the common source line 310, the bottom select line 309, and the top select line 308. The peripheral circuit 302 may include various types of peripheral circuits formed with metal-oxide-semiconductor technology.

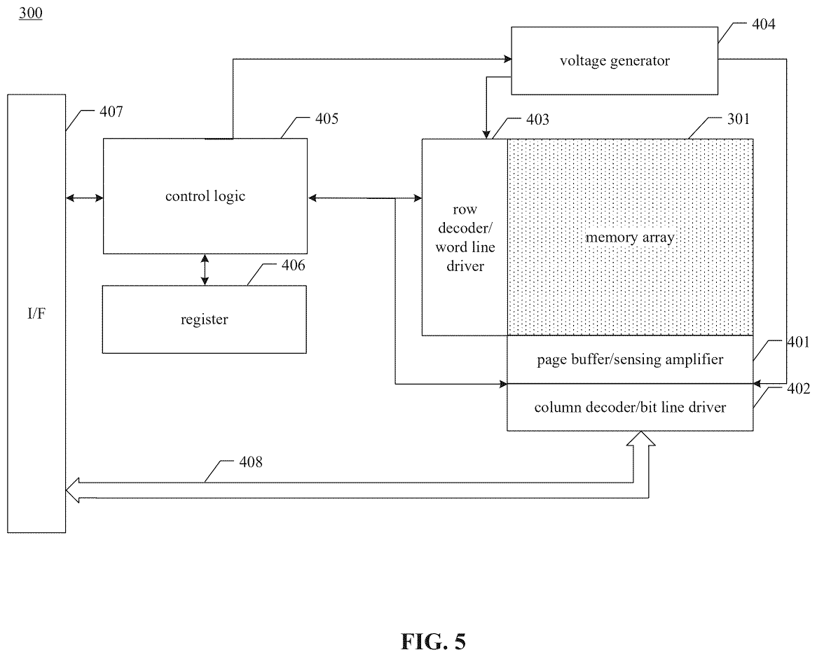

FIG. 5 shows some example peripheral circuits. For example, the peripheral circuit 302 includes a page buffer/sensing amplifier 401, a column decoder/bit line driver 402, a row decoder/word line driver 403, a voltage generator 404, a control logic 405, a register 406, a flash memory interface 407, and a data bus 408. It should be understood that, in some examples, additional peripheral circuit(s) not shown in FIG. 5 may be further included.

The page buffer/sensing amplifier 401 may be configured to read data from the memory cell array 301 and program (write) data to the memory cell array 301 according to a control signal from the control logic 405. In one example, the page buffer/sensing amplifier 401 may store a page of programming data (write data) to be programmed to the memory cell array 301. In another example, the page buffer/sensing amplifier 401 may perform a programming verification operation to ensure that the data has been properly programmed into memory cells coupled to the selected word line. In yet another example, the page buffer/sensing amplifier 401 may further sense a low-power signal from the bit line, representing a data bit stored in the memory cell, and may amplify a small voltage swing to an identifiable logic level in a read operation. The column decoder/bit line driver 402 may be configured to be controlled by the control logic 405 and select one or more memory cell strings by applying a bit line voltage generated from the voltage generator 404.

The row decoder/word line driver 403 may be configured to be controlled by the control logic 405 and select/deselect a memory block of the memory cell array 301 and select/deselect a word line of the memory block. The row decoder/word line driver 403 may be further configured to drive a word line using a word line voltage generated from the voltage generator 404. In some examples, the row decoder/word line driver 403 may further select/deselect and drive a bottom select line and a top select line. As described in detail hereinafter, the row decoder/word line driver 403 is configured to perform a programming operation on memory cells coupled to the selected word line(s). The voltage generator 404 may be configured to be controlled by the control logic 405 and generate a word line voltage (e.g., a reading voltage, a programming voltage, a passing voltage, a local voltage, a verifying voltage, etc.), a bit line voltage, and a source line voltage to be supplied to the memory cell array 301.

The control logic 405 may be coupled to each peripheral circuit described above, and configured to control operation of each peripheral circuit. The register 406 may be coupled to the control logic 405, and includes a status register, a command register, and an address register for storing status information, command operation code (OP code), and command address for controlling the operation of each peripheral circuit. The flash memory interface 407 may be coupled to the control logic 405 and act as a control buffer to buffer a control command received from a host-side device (not shown) and relay it to the control logic 405, and buffer status information received from the control logic 405 and relay it to a memory controller. The flash memory interface 407 may be further coupled to the column decoder/bit line driver 402 via the data bus 408, and act as a data I/O interface and a data buffer to buffer data and relay it to the memory cell array 301 or buffer and relay data from the memory cell array 301.

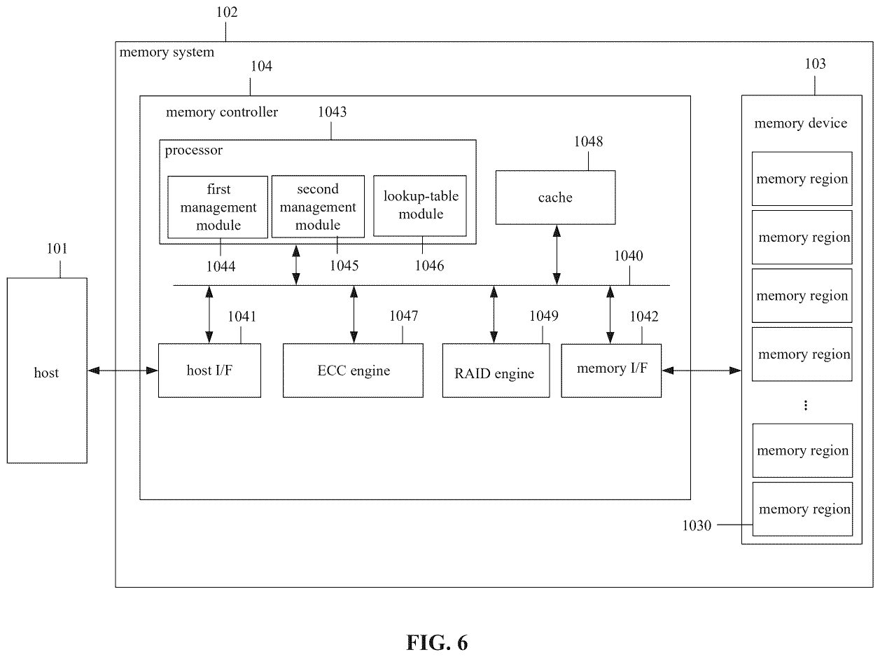

FIG. 6 is a schematic diagram of a system including a host and a memory system according to an implementation of the present disclosure.

As shown in FIG. 6, the memory system 102 is connected to the host 101, where the memory system 102 may include a memory controller 104 and a memory device 103. The memory controller 104 is configured to control the memory device 103 to perform operations such as read, write, and erase, etc. The memory controller 104 and the memory device 103 may be further coupled in any suitable manner. The memory controller 104 may include a host interface (I/F) 1041, a memory interface (I/F) 1042, a processor 1043, a cache 1048, and a bus 1040.

The host interface 1041 is a connection interface connected between the host 101 and the memory controller 104, the host interface 1041 allows the host 101 and the memory controller 104 to communicate according to a certain protocol, transmit read and write requests, and perform other operations.

The memory interface 1042 is a connection interface between the memory controller 104 and the memory device 103, the memory interface 1042 is configured to implement data transfer between the memory controller 104 and the memory device 103.

The processor 1043 is configured to integrally control the memory system 102.

In some examples, the processor 1043 may include one or more units having logical operation capability, for example, at least one of a Central Processing Unit (CPU) or a Micro Controller Unit (MCU), or the like.

It should be noted that the processor 1043 described in this implementations of the present application may include a plurality of functional modules, and each functional module of the processor 1043 may be a software module running on a processor (e.g., an MCU) as a part of the processor 1043, or may be a hardware module (e.g., an integrated circuit (IC), for example, an application-specific integrated circuit (ASIC), a field programmable gate array (FPGA), or the like)) of a finite state machine (FSM), or may be a combination of a software module and a hardware module.

In some implementations, the cache 1048 is configured to cache data, e.g., the data cached by the cache 1048 includes, but is not limited to, data received from the host 101, data to be sent to the host 101, data to be written to the memory device 103 (write data), data read from the memory device 103 (read data), and various management data representing the state of the memory device 103 and referenced by the processor 1043 for the control of the memory device 103.

For example, the cache 1048 includes, but is not limited to, a Random Access Memory (RAM), a Dynamic Random Access Memory (DRAM), a Static Random Access Memory (SRAM), a Synchronous Dynamic Random Access Memory (SDRAM), or a Double Data Rate (DDR) Synchronous Dynamic Random Access Memory (SDRAM) (DDR SDRAM).

In order to improve the reliability of data transmission and data storage, an Error-Correcting Code (ECC) technology has been widely used in the field of data storage, for example, in a variety of error-correcting codes, a Low Density Parity Check (LDPC) code is easy to decode, can perform parallel operations, and has become one of the most widely used error-correcting codes.

As a typical non-volatile semiconductor memory, a Not-And (NAND) type memory can be found in mainstream products in the storage market due to its high memory density, controllable production cost, and suitable erasing speed.

In a process of transferring and storing data in a NAND type memory, errors in data may be caused due to hardware faults, software faults, hard disk errors, etc. of the memory. To ensure the integrity of user data, it has been proposed to use LDPC codes to perform error detection and correction on data stored in a memory system including a NAND type memory.

To further meet the demand of storing and accessing reliable data, Redundant Array of Independent Disks (RAID) technology further improves the performance and reliability of memory systems including NAND type memories. RAID algorithms employ techniques of striping, mirroring, and/or parity check to achieve reliable data storage.

In some implementations, as shown in FIG. 6, the memory controller 104 further includes an error-correcting code (ECC) engine 1047 and a RAID engine 1049.

In some implementations, the error-correcting code engine 1047 may be configured to encode and decode data in the memory system using ECC techniques. For instance, the error-correcting code engine 1047 may include an encoder and a decoder. The encoder may be configured to perform ECC coding on the data to be written into the memory device in a writing operation; and the decoder may be configured to perform ECC decoding on the codeword to be decoded in the read data in a read operation.

In some implementations, the RAID engine 1049 may be configured to encode and decode data in a memory system using RAID techniques. For instance, the RAID engine 1049 may include an encoder and a decoder. The encoder may be configured to perform RAID coding on the data to be written into the memory device in a writing operation; and the decoder may be configured to perform RAID decoding on the codeword to be decoded in the read data in a read operation.

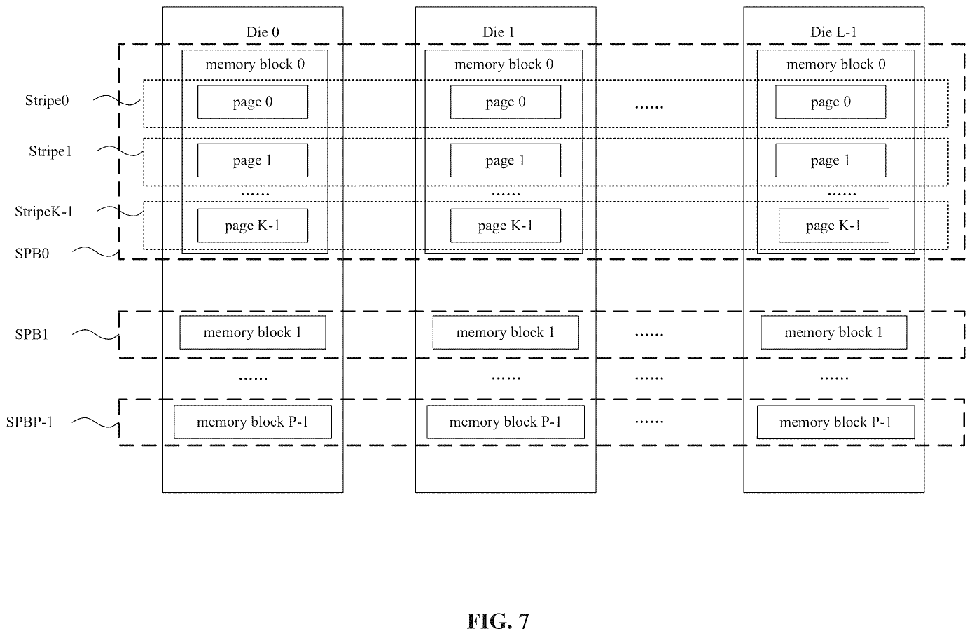

As shown in FIGS. 6 and 7, the memory device 103 includes a plurality of memory regions 1030. The memory region 1030 includes L dies, each of which is a die 0, a die 1, . . . , a die L-1 respectively, and L is an integer greater than 1. It can be understood that, when L is 4, the memory region 1030 includes 4 dies, namely, a die 0, a die 1, a die 2, and a die 3 respectively. Each die includes a plurality of memory blocks.

For example, FIG. 7 shows that each die includes P memory blocks, and the P memory blocks are respectively a memory block 0, a memory block 1, . . . , a memory block P-1, and P is an integer greater than 1. It may be understood that, when P is 4, each die includes 4 memory blocks, e.g., a memory block 0, a memory block 1, a memory block 2, and a memory block 3, respectively.

Memory controller 104 may manage multiple memory blocks in memory device 103. For instance, the memory controller 104 may group multiple memory blocks in different dies into one superblock; that is, multiple memory blocks in different dies form a superblock. For example, as shown in FIG. 7, the memory block 0 in each die form a superblock SPB0, and the memory block 1 in each die form a superblock SPB1, . . . , the memory block P-1 in each die form a superblock SPBP-1.

In some implementations, one superblock may include one or more stripes. In some implementations, the stripes may be referred to as super-page. A stripe or super-page may include a plurality of pages. For example, FIG. 7 shows that each memory block includes K pages, where the K pages are page 0, page 1, . . . , page K-1 respectively, and K is an integer greater than 1.

As shown in FIG. 7, pages 0 within memory blocks 0 within each die form stripes Stripe 0, pages 1 within memory blocks 0 within each die form stripes Stripe 1, . . . , pages K-1 within memory blocks 0 within each die form stripes Stripe K-1.

It should be noted that the memory blocks with the same ID in each die shown in FIG. 7 form one superblock. The same page with the same ID in each superblock form one stripe. The grouping manners of the superblock and the stripe are not limited thereto, and other manners known in the art may be further used.

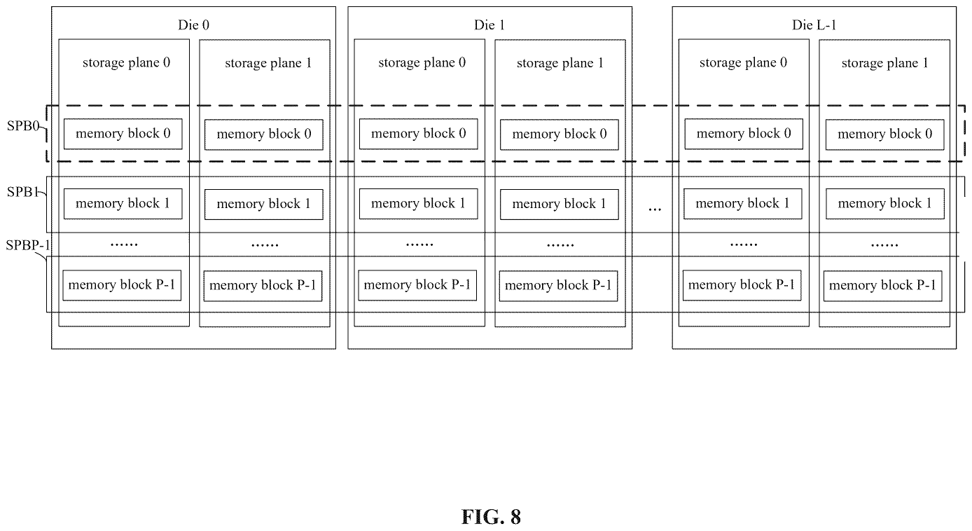

FIG. 8 is a schematic diagram of a storage plane, a memory block, and a superblock in a memory device according to an implementation of the present application. The superblock shown in FIG. 8 is different from the superblock shown in FIG. 7.

As shown in FIGS. 6 and 8, the memory device 103 includes a plurality of memory regions 1030. The memory region 1030 includes L dies, each of which is a die 0, a die 1, . . . , a die L-1, respectively; and L is an integer greater than 1. Each die includes a plurality of storage planes.

For example, FIG. 8 shows that each die includes two storage planes, and the two storage planes are a storage plane 0 and a storage plane 1, respectively. Each storage plane includes a plurality of memory blocks. For example, FIG. 8 shows that each storage plane includes P memory blocks, and the P memory blocks are a memory block 0, a memory block 1, . . . , a memory block P-1, respectively; and P is an integer greater than 1. It may be understood that, when P is 4, each storage plane includes 4 memory blocks, e.g., a memory block 0, a memory block 1, a memory block 2, and a memory block 3, respectively.

In some implementations, as shown in FIG. 8, the memory blocks 0 in the storage plane 0 and the storage plane 1 in each die form the superblock SPB0, the memory blocks 1 in the storage plane 0 and the storage plane 1 in each die form the superblock SPB1, . . . , the memory blocks P-1 in the storage plane 0 and the storage plane 1 in each die form the superblock SPB1P-1.

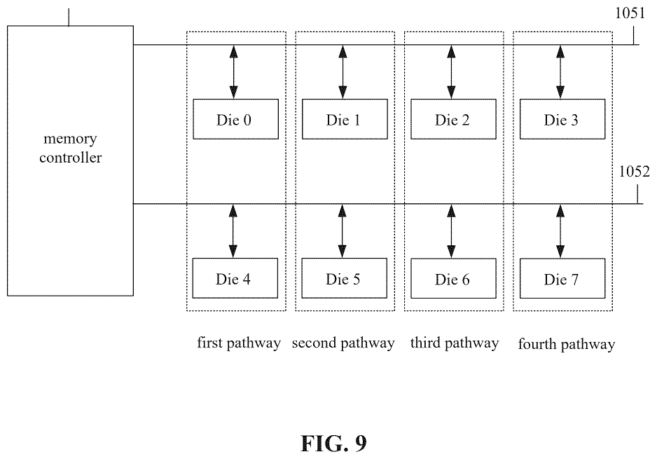

FIG. 9 is a schematic diagram of a channel layout between a memory controller and a memory device according to an implementation of the present application. As shown in FIG. 9, the memory controller 104 may be connected to a plurality of dies (die 0 to die 7) through a first channel 1051 and a second channel 1052.

For example, die 0, die 1, die 2, and die 3 may be commonly connected to first channel 1051 and communicate with memory controller 104 through first channel 1051.

For example, die 4, die 5, die 6, and die 7 may be commonly connected to second channel 1052 and communicate with memory controller 104 through second channel 1052.

Memory devices using multiple dies may improve performance by using data interleaving. To achieve data interleaving, memory devices may be managed in units of channels and pathways. For example, the memory controller 104 may send commands, control signals including addresses and data to the die 0 through the first channel 1051. The die 0 receives data sent from the memory controller 104. When die 0 programs data received from memory controller 104 to memory cells, memory controller 104 may send commands, control signals including addresses, and data to die 1.

In FIG. 9, the plurality of dies may be arranged to form four pathways (e.g., a first pathway, a second pathway, a third pathway, and a fourth pathway). The first pathway may include die 0 and die 4, the second pathway may include die 1 and die 5, the third pathway may include die 2 and die 6, and the fourth pathway may include die 3 and die 7.

Data interleaving of two channels and four pathways is depicted in FIG. 9. In actual use, data interleaving may be performed in other structures, and data interleaving may be more effective as the number of channels and the number of pathways increase.

As a non-limiting example, FIG. 9 depicts a memory region of a memory device that includes 8 dies, 2 channels, and 4 pathways. However, the examples of the present disclosure are not limited thereto.

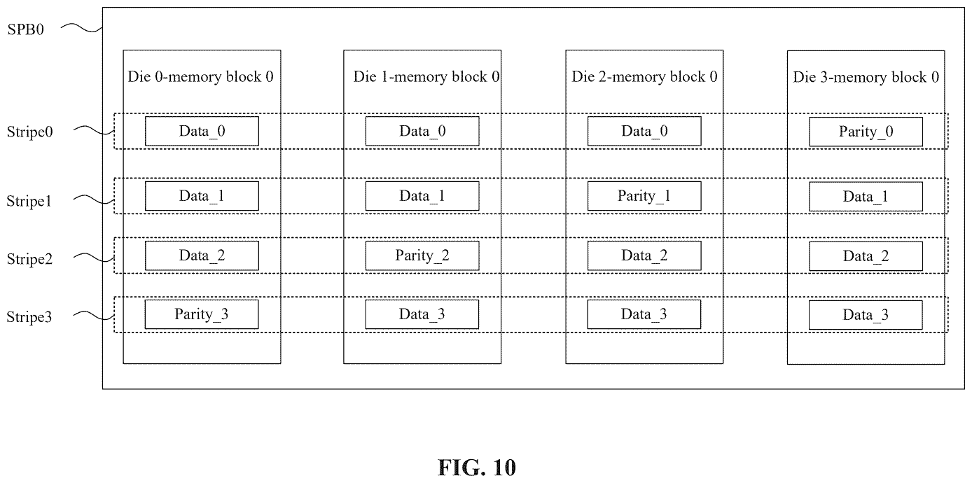

Next, the RAID 5 in the RAID technology is introduced in conjunction with FIG. 10. As shown in FIG. 10, the memory region of the memory device includes 4 dies (die 0, die 1, die 2, and die 3), and memory blocks 0 with the same ID in the 4 dies form the superblock SPB0, and each memory block includes 4 pages.

As shown in FIG. 10, pages 0 within memory blocks 0 within each die form stripes Stripe 0, pages 1 within memory blocks 0 within each die form stripes Stripe 1, pages 2 within memory blocks 0 within each die form stripes Stripe 2, pages 3 within memory blocks 0 within each die form stripes Stripe 3.

In some implementations, the RAID coding operation is performed on the received user data to generate check data, and the user data and the check data are written into the same superblock.

For example, as shown in FIG. 10, the user data and the check data are written into the superblock SPB0. For instance, an XOR operation is performed on the user data Data_0 to be written into the stripe Stripe 0 to generate the check data Parity_0, and the user data Data_0 and the check data Parity_0 are stored in the stripe Stripe 0.

The XOR operation is performed on the user data Data_1 to be written into the stripe Stripe1 to generate the check data Parity_1, and storing the user data Data_1 and the check data Parity_1 in the stripe Stripe1. The XOR operation is performed on the user data Data_2 to be written into the stripe Stripe 2 to generate the check data Parity_2, and storing the user data Data_2 and Parity_2 in the stripe Stripe 2. The XOR operation is performed on the user data Data_3 to be written into the stripe Stripe 3 to generate the check data Parity_3, and storing the user data Data_3 and the check data Parity_3 in the stripe Stripe 3.

Referring to FIG. 10, in the RAID 5 technique, check data is stored across all dies in the same superblock. For example, check data Parity_0, check data Parity_1, check data Parity_2, and check data Parity_3 are stored in die 3, die 2, die 1, and die 0 respectively.

In addition, in FIG. 10, the storage positions of the user data and the check data are described by taking the manner of applying Backward Dyn as an example. In some implementations, the check data starts from the last die (such as the die 3 shown in FIG. 10) and moves forward to the first die (the die 0 shown in FIG. 10) in sequence. When the RAID 5 technology is used, user data and check data may be stored in a manner including but not limited to Forward Dyn.

In the foregoing implementation, the check data is configured to verify the integrity of the user data, and ensure that the read data is not damaged or lost.

However, on one hand, storing the user data and the check data of the user data in same memory region (e.g., the same superblock of the same memory region) cannot implement independent management of the user data and the check data. For example, when the data migration or backup, the user data and the check data are processed together and cannot be operated separately. Consequently, the I/O burden is undesirably large or cannot be accessed using different modes according to the difference of data amount between the user data and the check data. On the other hand, the risk of data loss is increased, thereby reducing the reliability of the memory system when the superblock is damaged, while at the same time increasing the chance that the user data and the check data stored in the same superblock may be lost. This may result data that cannot be recovered.

Thus, there is an unmet need for a technique that improves the performance and reliability of the memory system.

To overcome these and other challenges, the present application provides the following implementations.

In some implementations, the present application provides a memory system. As shown in FIG. 6, the memory system 102 includes a memory controller 104 and a memory device 103 coupled to the memory controller 104. The memory device 103 includes a plurality of memory regions 1030.

The memory controller 104 is configured to perform a redundant array coding operation on the received user data to generate check data. The memory controller 104 is configured to allocate a first physical address storing the user data, where the first physical address points to a first memory region of the plurality of memory regions 1030. The memory controller 104 is configured to allocate a second physical address storing check data, and record the second physical address, where the second physical address points to a second memory region of the plurality of memory regions 1030 that is different from the first memory region. The memory controller 104 is configured to send a first writing instruction including the first physical address to the memory device, where the first writing instruction indicates to write the user data to the first memory region. The memory controller 104 is configured to send a second writing instruction that includes the second physical address and is different from the first writing instruction to the memory device, where the second writing instruction indicates to write the check data to the second memory region.

In the implementations of the present application, a redundant array coding operation is performed on the received user data to generate corresponding check data. The first physical address and the second physical address are allocated to the user data and the check data respectively, where the first physical address points to a first memory region of the plurality of memory regions and the second physical address points to a second memory region of the plurality of memory regions that is different from the first memory region.

The first writing instruction including the first physical address and the second writing instruction including the second physical address are sent to store the user data and the check data to the first memory region and the second memory region respectively.

On one hand, the implementations of the present application realize independent management of user data and check data by storing user data and check data separately, while at the same time improving the performance and flexibility of the memory system. In addition, it reduces the time for identifying the location of the check data by recording the second physical address, thereby improving the fault-tolerant capability and the data recovery speed of the memory system.

On the other hand, independent writing of user data and check data is realized through different writing instructions, and the first writing instruction and the second writing instruction independent of each other can further be processed in parallel, so that the data writing efficiency is further improved. In addition, the risk of simultaneous loss of user data and check data is reduced.

In some implementations, the user data includes, but is not limited to, data received from the host 101 and data received from the memory device 103. For example, the user data may be data received from the memory device 103 in a Garbage Collection (GC) stage or a Wear Leveling (WL) stage.

In some implementations, a redundant array coding operation includes a RAID coding operation.

In some implementations, the memory controller 104 may send the first writing instruction to the memory device through the first channel 1051 shown in FIG. 9, where the first writing instruction includes the first write command, the first physical address, and the user data, and the first memory region of the memory device receives the user data sent from the memory controller 104. When a first memory region of the memory device (e.g., die 0 to die 3) programs user data received from memory controller 104 to a memory cell, memory controller 104 may send a second writing instruction to a second memory region of the memory device (e.g., die 4) through second channel 1052, where the second writing instruction includes a second write command, a second physical address, and check data.

In some implementations, timings of the first writing instruction and the second writing instruction are different.

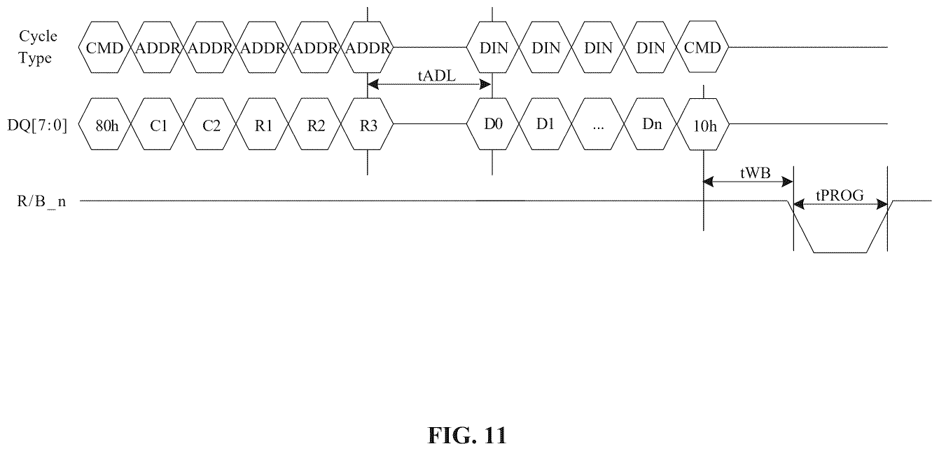

FIG. 11 is one of timing diagram of a writing operation according to an implementation of the present disclosure.

As shown in FIG. 11, Cycle Type represents an input type; CMD represents an input command input; ADDR represents an address input; DIN represents input data (data in); DQ [7:0] represents a chip pin having an input/output function; R/B_n represents a chip pin for monitoring a chip state (busy/ready), and a low level represents a busy state; tADL represents an time interval between address input to data input (address cycle to data loading time); and tWB represents a time interval from a command to R/B_n pull down.

For example, the first writing instruction that indicates to perform the first writing operation may include, for example, two sub-commands (e.g., 80h and 10h). In an example implementation, after receiving the sub-command 80h, the memory device 103 receives the address ADDR of the user data about which the write/program operation is to be performed. After receiving the address ADDR, the memory device 103 may receive user data DATA about which the write/program operation is to be performed. After receiving the sub-command 10h, the memory device 103 writes the user data DATA to the first memory region within the write/program time tPROG.

For example, the second writing instruction that indicates to perform the second writing operation may further include, for example, two sub-commands (e.g., 80h and 10h). In an example implementation, after receiving the sub-command 80h, the memory device 103 receives the address ADDR of the check data to be executed. After receiving the address ADDR, the memory device 103 may receive check data to perform a write/program operation. After receiving the sub-command 10h, the memory device 103 writes the check data to the first memory region within the write/program time tPROG.

It should be noted that FIG. 11 may represent a timing diagram for performing a first writing operation, or may represent a timing diagram of a second writing operation, where two sub-commands of the first writing instruction and the second writing instruction are the same.

In a first writing operation where user data is written into the first memory region and a second writing operation where the check data is written into the second memory region, the first writing instruction includes the first physical address and the user data, and the second writing instruction includes the second physical address and the check data.

In other words, in the timing diagram shown in FIG. 11, there is a difference between the address ADDR after sub-command 80h and the data DATA before sub-command 10h between the first writing instruction and second writing instruction.

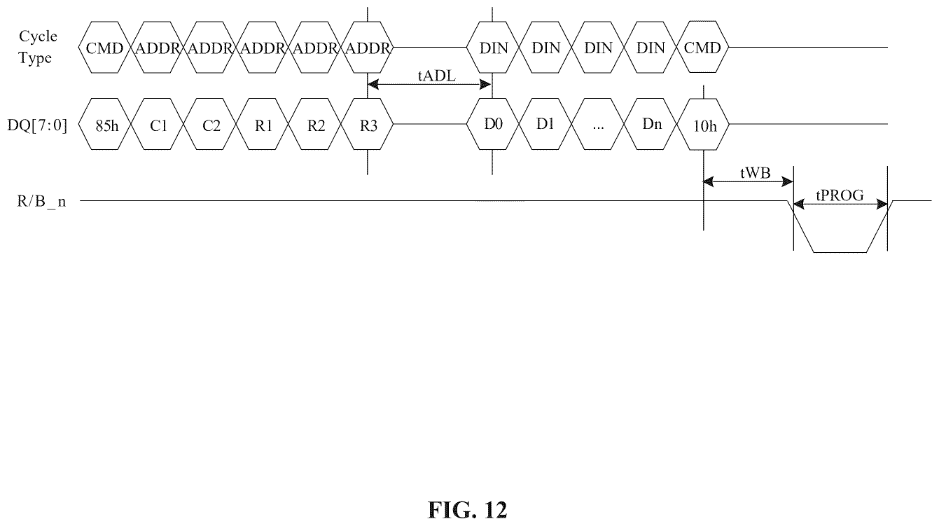

FIG. 12 is a second timing diagram of performing a writing operation according to an implementation of the present application.

As shown in FIG. 12, the second writing instruction for indicating the execution of the second writing operation may include, for example, two sub-commands (e.g., 85h and 10h). In an example implementation, after receiving the sub-command 85h, the memory device 103 receives the address ADDR of the check data to be written/programmed. After receiving the address ADDR, the memory device 103 may receive check data to perform a write/program operation. After receiving the sub-command 10h, the memory device 103 writes the check data to the second memory region within the write/program time tPROG.

It should be noted that in the above implementations, the sub-command 85h of the second writing instruction is predefined to indicate that the write of the check data is started, and to ensure that the user data and the check data are written into different memory regions by distinguishing the sub-command 85h of the second writing instruction and the sub-command 80h of the first writing instruction. In actual use, on the premise that the first writing instruction and the second writing instruction are different, the sub-commands in the first writing instruction and the second writing instruction may be further predefined as other types of sub-commands.

In some implementations, the first memory region includes a plurality of first dies, and the first die includes a plurality of first memory blocks, where a plurality of first memory blocks in different first dies form a superblock; and the memory controller is configured to allocate a first physical address based on the plurality of managed superblocks, where the first physical address points to a target superblock in the plurality of superblocks.

In some implementations, the second memory region includes at least one second die, and the second die includes a plurality of second memory blocks. The memory controller is further configured to allocate a second physical address based on the plurality of managed second memory blocks, where the second physical address points to a target second memory block in the plurality of second memory blocks.

In some implementations, the memory controller is further configured to manage the plurality of superblocks and the plurality of second memory blocks.

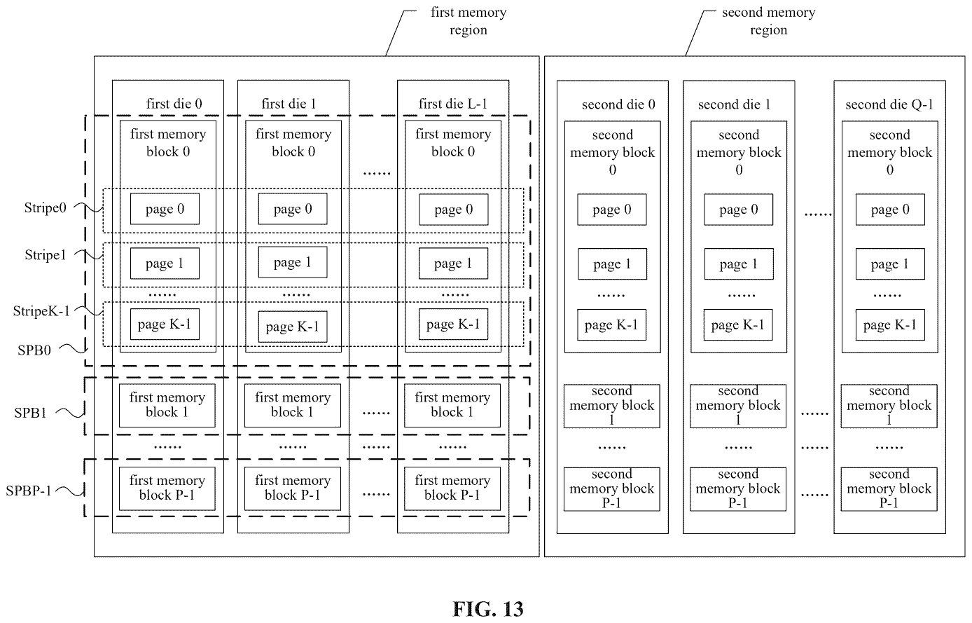

With reference to FIG. 6 and FIG. 13, a first memory region of the plurality of memory regions 1030 of the memory device 103 includes L first dies, and the L first dies are a first die 0, a first die 1, . . . , a first die L-1 respectively, and L is an integer greater than 1.

It can be understood that, when L is 4, the memory region 1030 includes 4 first dies, namely, the first die 0, the first die 1, the first die 2, and the first die 3 respectively. Each first die includes a plurality of first memory blocks.

For example, FIG. 13 shows that each first die includes P first memory blocks, and the P first memory blocks are a first memory block 0, a first memory block 1, . . . , a first memory block P-1, respectively, and P is an integer greater than 1.

It may be understood that, when P is 4, each first die includes 4 first memory blocks, namely, a first memory block 0, a first memory block 1, a first memory block 2, and a first memory block 3, respectively.

The second memory region of the plurality of memory regions 1030 of the memory device 103 includes Q second dies, and the Q second dies are the second die 0, the second die 1, . . . , the second die Q-1 respectively, and Q is an integer greater than or equal to 1. Each second die includes a plurality of second memory blocks. For example, FIG. 13 shows that each second die includes P second memory blocks, and the P second memory blocks are the second memory block 0, the second memory block 1, . . . , the second memory block P-1 respectively, and P is an integer greater than 1.

Herein, a plurality of first memory blocks in different first dies in the first memory region form a superblock. For example, the first memory blocks with the same ID in each first die shown in FIG. 13 forms a superblock and the pages with the same ID in each superblock forms a stripe. A division manner of the superblock and the stripe may refer to FIG. 7 and related descriptions thereof, and details are not described herein again.

In some implementations, the number of the first dies included in the first memory region and the number of the second dies included in the second area may be the same or different.

In some implementations, since the data amount of the user is greater than the data amount of the check data, the number of the first dies included in the first memory region is greater than the number of the second dies included in the second area, ; for example, L is greater than Q.

In some implementations, the first physical address points to a target superblock in a plurality of superblocks, where the number of target superblocks may be one or more, and the number of target superblocks depends on a size of data amount of the user data actually to be written.

Similarly, a number of target second memory blocks may be one or more, and a number of target second memory blocks depends on a size of data amount of the check data actually to be written.

According to the implementations of the present application, different management granularities (superblocks and memory blocks) are adopted in the first memory region and the second memory region according to the data amount difference of the user data and the check data to realize efficient management of the user data and fine control of the check data. This differentiation strategy optimizes storage resource allocation, improves the overall performance of the memory system, and balances the flexibility and efficiency of data management.

In some implementations, the memory controller is further configured to obtain first metadata related to the user data from the memory device, where the first metadata includes index information related to check data; and the memory controller is further configured to retrieve the mapping table based on the index information to determine a second physical address for storing the check data, where the mapping table includes a mapping relationship between the index information and the second physical address.

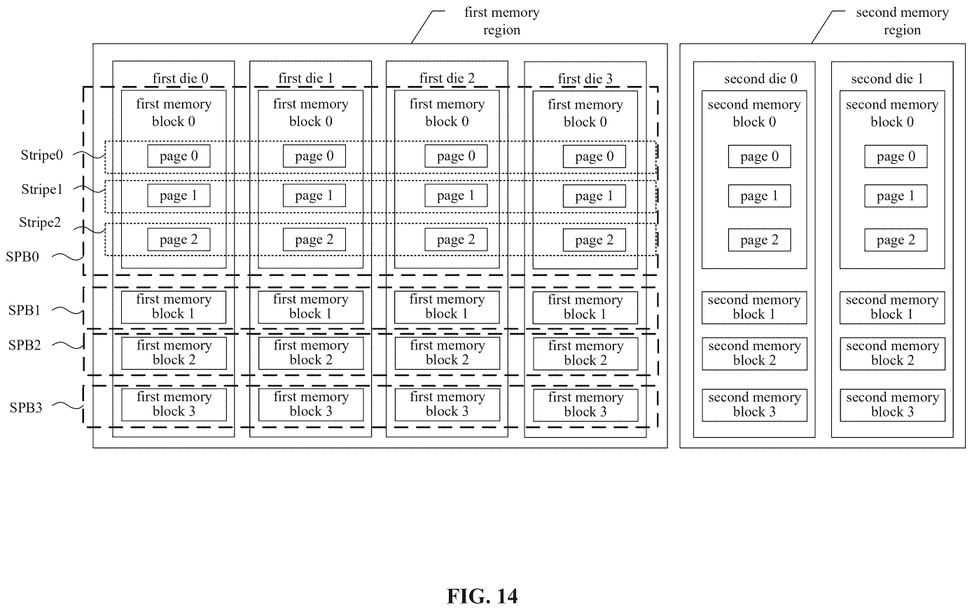

In some implementations, as shown in FIG. 14, the first memory region includes 4 first dies (e.g., the first die 0, the first die 1, the first die 2, and the first die 3), and each first die includes 4 first memory blocks. The second memory region includes 2 second dies, each second die including 4 second memory blocks.

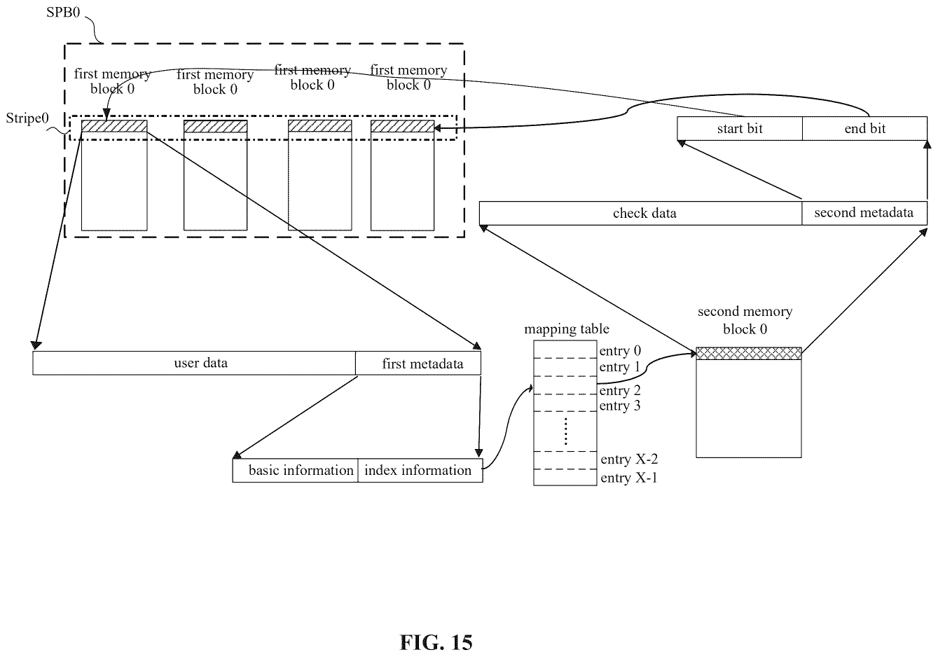

FIG. 15 is a schematic diagram of a relationship between user data stored in one superblock and check data stored in a second memory block shown in FIG. 14.

As shown in FIG. 14 and FIG. 15, when the user data is written into the superblock SPB0 of the first memory region, the first metadata is further written into the superblock SPB0 of the first memory region. For example, the user data and the first metadata are stored in a same page (Page) of the first memory block 0 of the superblock SPB0.

In some implementations, the first metadata includes basic information and index information related to the check data. The basic information includes, but is not limited to, a mapping relationship between a logical address and a physical address of the user data, wear leveling information (e.g., a number of erasing times of the memory block), a timestamp (recording the writing time of the data), and the like.

In some implementations, in the powering up stage, the memory controller 104 loads the mapping table from the memory device 103, e.g., loads the mapping table into the cache 1048 of the memory controller 104 to support fast access and real-time update. Upon powering down, the memory controller writes the mapping table back into the memory device 103.

In some implementations, the mapping table includes a plurality of entries, and one entry records a second physical address corresponding to one piece of index information; the memory controller is further configured to retrieve the mapping table based on the index information to determine a target entry in the plurality of entries; and determine the second physical address storing check data based on the target entry.

As shown in FIG. 15, the mapping table includes X entries, where X entries are respectively an entry 0, an entry 1, an entry 2, an entry 3, . . . , an entry X-2, and an entry X-1, where X is an integer greater than or equal to 1.

In some implementations, the superblock includes at least one stripe, the first physical address points to a target stripe of a plurality of stripes of the target superblock, and the target stripe is configured to store user data. The memory controller is configured to determine a corresponding second identifier in the index information based on the first identifier in the index information, where the first identifier is configured to indicate a position of the target stripe, and the second identifier is configured to indicate a position of the target entry. The memory controller is configured to obtain the target entry based on the second identifier.

Herein, reference may be made to the relationship between the superblock and the stripe in FIG. 7 and FIG. 13 for understanding, and details will not be described again here.

In some implementations, the number of the target stripes may be one or more, and the number of the target stripes depends on the size of the data amount of the user data.

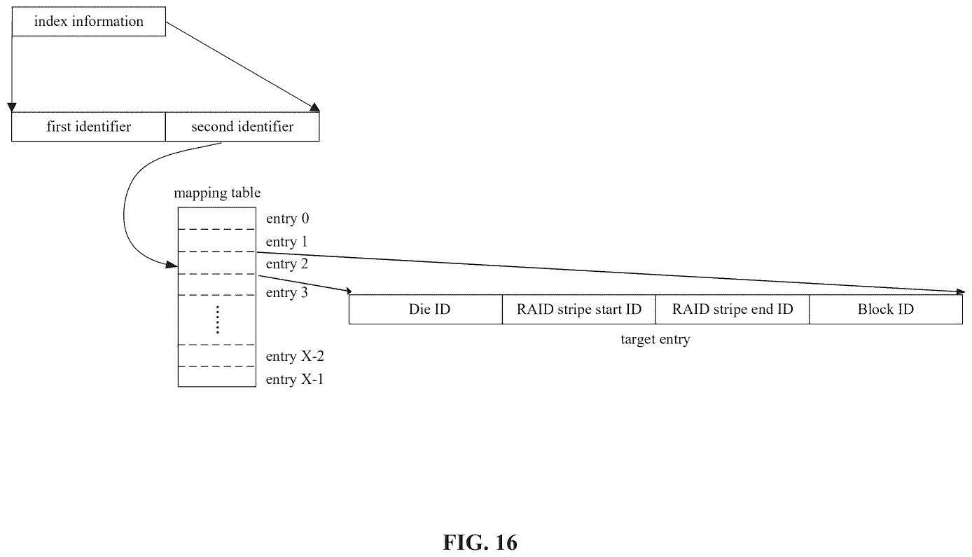

FIG. 16 is a schematic diagram of a relationship between index information and a mapping table. As shown in FIG. 16, the index information includes a first identifier and a second identifier. The memory controller can determine the position of the target stripe by the first identifier, and determine the position of the target entry by the second identifier to further obtain the target entry.

In some implementations, as shown in FIG. 16, the information about the second physical address recorded in the entry of the mapping table includes at least: a Die ID and a Block ID.

In some other implementations, when the check data is stored in the superblock including second memory blocks with the same ID of the second memory region shown in FIG. 14, the information about the second physical address recorded in the entry of the mapping table includes at least: a Die ID, a Raid stripe start ID, a Raid stripe end ID, and a Block ID.

In some implementations, when the check data is stored in the superblock including the same numbered second memory blocks of the second memory region shown in FIG. 14, the information about the second physical address recorded in the entry of the mapping table includes at least: Die ID, a Raid stripe start ID, an address offset and a Block ID, and the Raid stripe end ID may be determined by the Raid stripe start ID and the address offset.

It should be noted that, in this case, the number of the second memory blocks in the superblock configured to store check data is less than the number of the first memory blocks in the superblock configured to store user data.

In other implementations, the index information includes a logical address of check data and a mapping relationship between a logical address and a physical address of the check data.

In some implementations, the memory controller is configured to allocate a blank entry of the plurality of entries and record the second physical address into the blank entry.

As shown in FIG. 15, the entry 2 in the mapping table is a blank entry, and in some implementations, the blank entry represents an entry of unrecorded information in a plurality of entries of the mapping table.

In other implementations, when a plurality of entries of the mapping table are all recorded with information, a blank entry may be provided for the second physical address to be recorded by adding a blank entry in the mapping table.

In some implementations, the memory controller is further configured to obtain second metadata related to the check data from the memory device, where the second metadata includes address information related to the user data; the memory controller is further configured to determine that an error occurs in the second physical address recorded in the target entry based on the address information in the second metadata does not match the first physical address; and the memory controller is further configured to reconstruct the target entry based on an error that occurs in the second physical address recorded in the target entry.

In some implementations, the memory controller is further configured to determine that the second physical address recorded in the target entry is correct based on the address information in the second metadata matches the first physical address.

In some implementations, as shown in FIG. 15, when the check data is written into the second memory block of the second memory region, the second metadata is further written into the second memory block of the second memory region. For example, the user data and the second metadata are stored in the same page of the second memory block 0 of the second memory region.

In some implementations, the address information in the second metadata includes a start bit storing a physical address of the user data and an end bit storing a physical address of the user data. For example, as shown in FIG. 15, the address information in the second metadata includes the start bit and the end bit of the stripe Stripe 0 of the superblock SPB0 storing the user data.

In the implementations of the present application, the storage position (e.g., the first physical address) of the user data corresponding to the check data may be determined based on the address information in the second metadata. When the address information in the second metadata does not match the first physical address, it indicates that the check data obtained based on the second physical address recorded in the target entry in the mapping table does not match the user data. In other words, an error occurs in the second physical address recorded in the target entry. Therefore, the target entry may be reconstructed.

For instance, other user data and other first metadata stored at the physical address corresponding to the address information may be obtained according to the obtained address information of the second metadata; other entries in the mapping table may be re-retrieved via the index information in the other first metadata; and when the address information of the second metadata obtained according to the latest retrieved other entries matches the physical address of the other user data, it is determined that the second physical address recorded in the other entry that is latest retrieved is correct, and the target entry in which the error occurs is modified according to the information recorded in the latest other entry.

When the address information in the second metadata matches the first physical address, it indicates that the check data obtained based on the second physical address recorded in the target entry in the mapping table matches the user data; that is, the second physical address recorded in the target entry is correct.

According to the implementation of the present application, the error entry in the mapping table can be quickly located and repaired by the matching condition of the address information of the second metadata and the first physical address so that the data reading failure caused by errors of the mapping table is avoided. By dynamically reconstructing the entries of the mapping table, the reliability of the mapping table can be ensured, the data access reliability is improved, while at the same time reducing the data loss or damage risk caused by mapping errors, and enhancing the fault-tolerant capability and long-term stability of the memory system.

In some implementations, the memory cells of the first memory region and the memory cells of the second memory region are respectively configured in different storage modes.

In some implementations, the memory cell of the first memory region is configured to store M-bit data, and the memory cell of the second memory region is configured to store N-bit data; where both M and N are integers greater than 1, and N is less than M.

In some implementations, the storage mode may be an SLC mode, an MLC mode, a TLC mode, a QLC mode, or a PLC mode.

In some implementations, the storage mode of the memory cell of the first memory region is configured as the QLC mode, and the storage mode of the memory cell of the second memory region is configured as the SLC mode. In other words, the memory cell of the first memory region is configured to store 4-bit data, and the memory cell of the second memory region is configured to store 1-bit data. It may be understood that, when the user data is stored in the first memory region and the check data is stored in the second memory region, different storage modes are configured to store the user data and the check data.

In the implementation of the present application, the plurality of memory regions of the memory device are divided into a first memory region and a second memory region. The first memory region is configured to store user data with high capacity requirements. The second memory region is configured to store check data with high reliability requirements. Different storage modes are adopted in the first memory region and the second memory region. The storage space can be fully utilized. The performance of the memory system can be effectively optimized.

In other examples, N may be equal to M.

In some implementations, the memory controller 104 is further configured to obtain user data stored in the first memory region from the memory device 103; the memory controller 104 is further configured to send a reading instruction including the second physical address to the memory device based on an error-correcting code check performed on the obtained user data fails, where the reading instruction indicates to read the check data stored in the second memory region; and the memory controller 104 is further configured to perform a redundant array check on the user data by using the read check data.

According to a second aspect, an implementation of the present application provides a memory system. The memory system may include a memory controller and a memory device coupled to the memory controller, where the memory device includes a plurality of dies, and the plurality of dies are divided into a plurality of memory regions. The memory controller is configured to migrate a partial user data stored in the faulty die in the first memory region to a target memory block in the first memory region based on the at least one faulty memory block exists in a first memory region of the plurality of memory regions; the memory controller is configured to update a first physical address of the user data based on the partial user data is migrated to a target memory block in the first memory region, where the first physical address points to the first memory region; the memory controller is configured to re-perform a redundant array coding operation on a partial user data migrated to a target memory block in the first memory region and remaining user data that is not migrated in the first memory region to generate first check data; the memory controller is configured to allocate a third physical address storing the first check data, and record the third physical address, where the third physical address points to a second memory region of the plurality of memory regions that is different from the first memory region; and the memory controller is configured to send a third writing instruction including the third physical address to the memory device, where the third writing instruction indicates to write the first check data to the second memory region.

In some implementations, the memory controller is configured to determine a memory region in which the faulty memory block is located based on the at least one faulty memory block exists in the plurality of dies.

In some implementations, the faulty memory block may be further referred to as a bad block, as shown in FIG. 14, when the number of error bits of one or more pages in the first memory block 0 of the first die 0 exceeds a threshold, the first memory block 0 is identified as a faulty memory block.

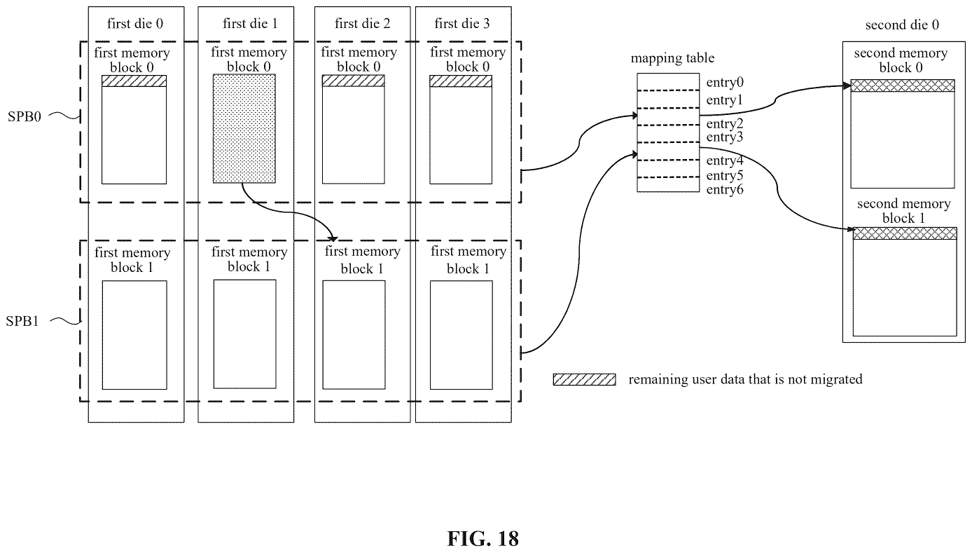

In some implementations, as shown in FIG. 14 and FIG. 18, the first memory block 0 in the first die 1 in the first memory region is a faulty memory block, and the remaining first memory blocks in the first die 1 are qualified memory blocks. For example, when performing data migration on the partial user data stored in the first memory block 0 in the first die 1, the target memory block in the first memory region may be the first memory block 1 of the first die 1 or the first memory block 1 of the first die 2.

It should be noted that the target memory block may be an idle first memory block in the first storage area or an occupied first memory block satisfying a capacity, the occupied first memory block indicates that the data is not fully written, and a remaining storage capacity is greater than or equal to the size of data amount of the user data.

In some implementations, a redundant array coding operation (e.g., a RAID coding operation) is re-performed on the partial user data migrated to the target memory block in the first memory region and remaining user data that is not migrated in the first memory region to generate first check data; a third physical address for storing the first check data is allocated, and a third physical address is recorded, where the third physical address points to a second memory region of the plurality of memory regions that is different from the first memory region. For example, the third physical address points to the second memory block 1 in the second die 0 in the second memory region.

In the implementations of the present application, when a memory block in which the partial user data is located is faulty, data migration may not be performed on data in all the memory blocks involved in the superblock in which the user data is located, and the first check data can be regenerated based on the migrated partial user data and the unmigrated remaining user data, the first check data is stored in the second memory region, and the reliability of the memory system is ensured while the data migration amount is reduced.

In some implementations, the memory controller is configured to determine that the at least one die is a faulty die based on the number of faulty memory blocks in the at least one of the plurality of dies being greater than a preset threshold.

In some implementations, the preset threshold may be an upper limit value of the allowed number of bad blocks preset by the test data statistical analysis according to chip design specifications, process maturity and reliability requirements.

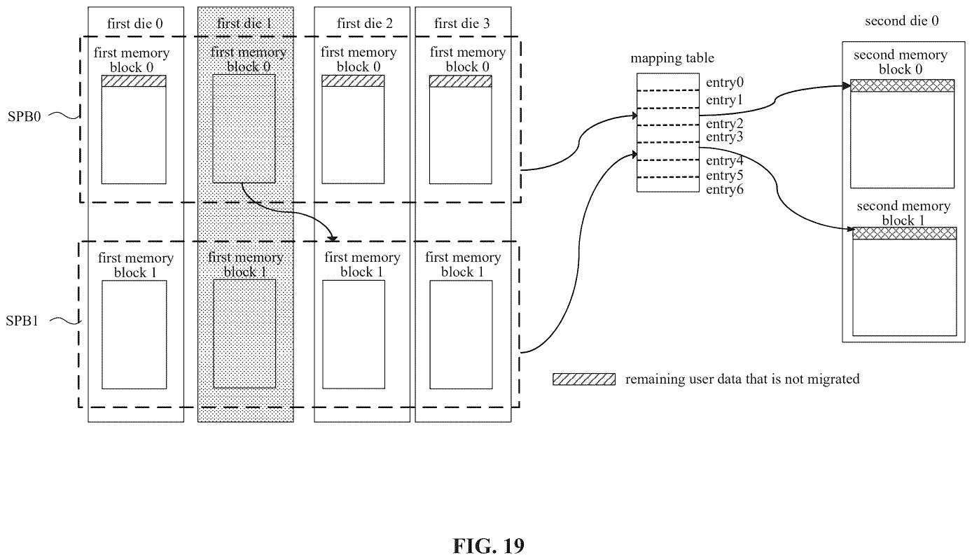

In some implementations, with reference to FIG. 14 and FIG. 19, the die failure in which the superblock SPB0 in the first memory region is located migrates partial user data stored in the first memory block 0 of the faulty die (e.g., the first die 1) in the first memory region to a qualified die in the first memory region, for example, in the first memory block 1 of the qualified die in the superblock SPB1 of the first memory region.

It should be noted that, when data migration is performed on the partial user data stored in the faulty die in the first memory region, because the first die 1 in FIG. 19 is a faulty die, in the process of migrating partial user data from the superblock SPB0 to the superblock SPB1 as shown in FIG. 16, the first physical address allocated to the user data to be migrated will avoid the first memory block 1 belonging to the faulty die (the first die 1) in the superblock SPB1 and point to the first memory block 1 belonging to other qualified dies (for example, the first die 0, the first die 2, and the first die 3) in the superblock SPB1.

In some implementations, a redundant array coding operation (e.g., a RAID coding operation) is re-performed on the partial user data migrated to the qualified die in the first memory region and remaining user data that is not migrated in the first memory region to generate first check data; a third physical address for storing the first check data is allocated, and a third physical address is recorded, where the third physical address points to a second memory region of the plurality of memory regions that is different from the first memory region. For example, the third physical address points to the second memory block 1 in the second die 0 in the second memory region.

In the implementations of the present application, when a die in which partial user data is located is faulty, data migration does may not be performed on data in all the dies in the superblock in which the user data is located, and the first check data can be regenerated based on the migrated partial user data and the unmigrated remaining user data, the first check data is stored in the second memory region, and the reliability of the memory system is ensured while the data migration amount is reduced.

In some implementations, the memory controller is further configured to re-perform a redundant array coding operation on the user data stored in the first memory region based on the at least one faulty memory block exits in the second memory region to generate second check data; the memory controller is further configured to allocate a fourth physical address for storing the second check data, and record the fourth physical address, where the fourth physical address points to a target memory block in the second memory region; and the memory controller is further configured to send a fourth writing instruction including the fourth physical address to the memory device, where the fourth writing instruction indicates to write the second check data to the target memory block in the second memory region.

In the implementations of the present application, when the memory block in which the check data is located is faulty, data migration may not be performed on the data in all the memory blocks involved in the superblock in which the user data is located, and the user data in the first memory region can regenerate the second check data, and the second check data is stored in the second memory region, thereby ensuring the reliability of the memory system while reducing the data migration amount.

In some implementations, the first memory region includes a plurality of first dies, and the first die includes a plurality of first memory blocks, where a plurality of first memory blocks in different first dies form a superblock; and the memory controller is configured to allocate a first physical address based on the plurality of managed superblocks, where the first physical address points to a target superblock in the plurality of superblocks.

In some implementations, the second memory region includes at least one second die, and the second die includes a plurality of second memory blocks; and the memory controller is further configured to allocate a fourth physical address based on the plurality of managed second memory blocks, where the fourth physical address points to a target second memory block in the target second die.

In some implementations, the memory controller is further configured to manage the plurality of superblocks and the plurality of second memory blocks.

Herein, a division manner of the first memory region and the second memory region in the plurality of memory regions and a division manner of the superblock in the first memory region may refer to related descriptions in FIG. 13 to FIG. 14. Details are not described herein again.

According to the implementations of the present application, by separately storing the user data and the check data through the first memory region and the second memory region, thereby realizing independent management of the user data and the check data, the data amount of the migrated data is reduced when the memory block in which the user data or the check data is located is reduced, the burden on the memory system is reduced, and the risk of loss of both user data and check data is also reduced.

In some implementations, the memory controller is further configured to obtain third metadata related to the user data from the memory device, where the third metadata includes index information related to the first check data; and the memory controller is further configured to retrieve a mapping table based on the index information to determine a third physical address for storing the first check data, where the mapping table includes a mapping relationship between the index information and the third physical address.

Here, the third metadata may be understood with reference to the related description of the first metadata in the foregoing implementations.

In some implementations, the mapping table includes a plurality of entries, and one entry records a third physical address corresponding to one piece of index information; the memory controller is further configured to retrieve a mapping table based on the index information to determine a target entry in the plurality of entries; and determine a third physical address for storing the first check data based on the target entry.

As shown in FIG. 13, the mapping table includes X entries, where X entries are respectively an entry 0, an entry 1, an entry 2, an entry 3, . . . , an entry X-2, and an entry X-1, where X is an integer greater than or equal to 1.

As shown in FIG. 16, the mapping table includes 7 entries, and the third physical address for storing the first check data is determined based on the target entry (entry 4 shown in FIG. 7).

In some implementations, the superblock includes at least one stripe, the updated first physical address points to a target stripe of the plurality of stripes of the target superblock, and the target stripe is configured to store user data; the memory controller is further configured to determine a corresponding second identifier in the index information based on the first identifier in the index information, where the first identifier is configured to indicate a position of the target stripe, and the second identifier is configured to indicate a position of the target entry; and the memory controller is further configured to obtain the target entry based on the second identifier.

In some implementations, the memory controller is further configured to allocate a blank entry of the plurality of entries, and record the third physical address into the blank entry.

In some implementations, the blank entry represents an entry of unrecorded information in the plurality of entries of the mapping table.

In other implementations, when the plurality of entries of the mapping table are all recorded with information, a blank entry may be provided for the third physical address to be recorded by adding a blank entry in the mapping table.

In some implementations, the memory controller is further configured to obtain fourth metadata related to the first check data from the memory device, where the fourth metadata includes address information related to the user data; determine that an error occurs in the third physical address recorded in the target entry based on the address information in the fourth metadata does not match the updated first physical address; and the memory controller is further configured to reconstruct the target entry based on an error that occurs in the third physical address recorded in the target entry.

Here, the fourth metadata may be understood with reference to the related description of the second metadata in the foregoing implementations.

In some implementations, the memory controller is further configured to determine that the third physical address recorded in the target entry is correct based on the address information in the fourth metadata matches the new first physical address.

In some implementations, the address information in the fourth metadata includes a start bit for storing a physical address of the user data and an end bit for storing a physical address of the user data.

In some implementations, the memory cells of the first memory region and the memory cells of the second memory region are respectively configured in different storage modes.

In some implementations, the memory cell of the first memory region is configured to store M-bit data, and the memory cell of the second memory region is configured to store N-bit data, where both M and N are integers greater than 1, and N is less than M. In the implementations of the present application, the plurality of memory regions of the memory device are divided into a first memory region and a second memory region, where the first memory region is used for storing user data with high capacity requirements, the second memory region is used for storing check data with high reliability requirements, different storage modes are adopted in the first memory region and the second memory region, the storage space can be fully utilized, and the performance of the memory system can be effectively optimized.

In some implementations, the memory controller is configured to determine a memory region in which the faulty memory block is located based on the at least one faulty memory block exists in the plurality of dies.

In some implementations, the memory controller is configured to determine that the at least one die is a faulty die based on the number of faulty memory blocks in the at least one of the plurality of dies being greater than a preset threshold.

In some implementations, the memory controller is further configured to obtain user data stored in the first memory region from the memory device; the memory controller is further configured to send a reading instruction including the second physical address to the memory device based on an error-correcting code check performed on the obtained user data fails, where the reading instruction indicates to read the first check data stored in the second memory region; and the memory controller is further configured to perform a redundant array check on the user data by using the read first check data.

In some implementations, the memory system includes a solid state disk, a universal flash memory, or an embedded multimedia card.

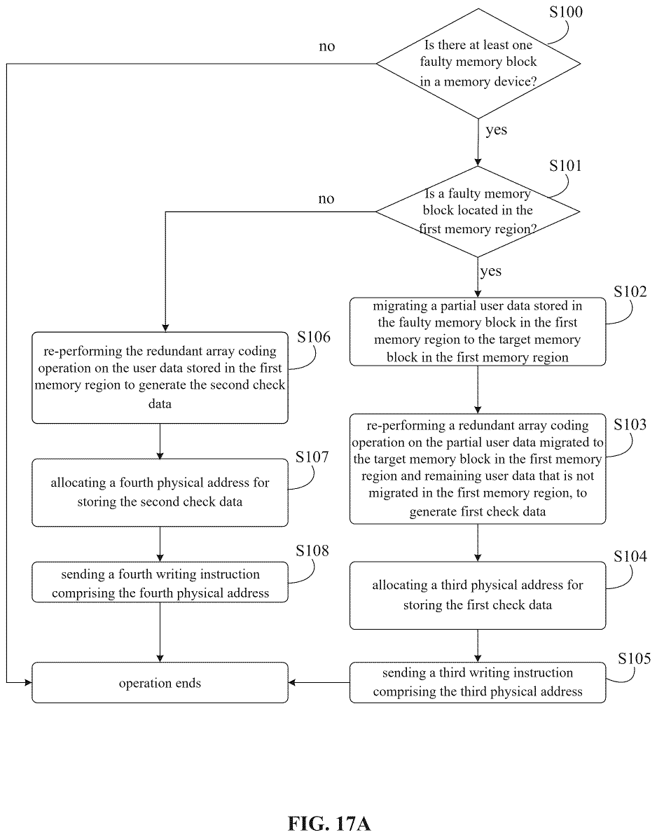

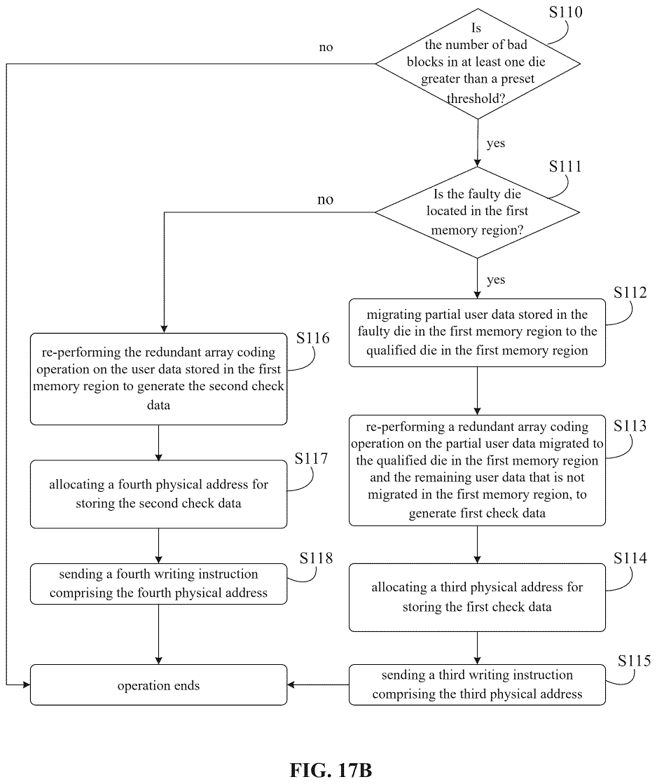

FIG. 17A is a first flowchart of a method of operating a memory system according to an implementation of the present application. Referring to FIG. 17A, the method may include operations S100-S108.

As shown in FIG. 17A, at S100, at least one faulty memory block may be determined to exist in the memory device. If the determination result of S100 is “no”, the operation ends.

If the determination result of S100 is “yes”, S101 is performed.

At operation S101, whether the faulty memory block is located in the first memory region may be determined; in other words, whether the memory block in which the user data is located is faulty or the memory block in which the check data is located is faulty may be determined.

If the determination result in S101 is “yes”, indicating that the memory block in which the user data is located is faulty, S102 is performed.

The memory block in the first memory region includes the target memory block and the faulty memory block. At operation S102, a partial user data stored in the faulty memory block in the first memory region is migrated to the target memory block in the first memory region. Herein, the target memory block may also be construed as other qualified memory blocks other than the faulty memory block in the first memory region.

At operation S103, a redundant array coding operation is re-performed on the partial user data migrated to the target memory block in the first memory region and remaining user data that is not migrated in the first memory region to generate first check data.

At operation S104, a third physical address may be allocated for storing the first check data.

At operation S105, a third writing instruction including the third physical address may be sent to the memory device, and the operation ends.

If the determination result of S101 is “no,” indicating that the memory block in which the check data is located is faulty, then proceeding to operation S106, the redundant array coding operation may be re-performed on the user data stored in the first memory region to generate the second check data.

At operation S107, a fourth physical address may be allocated for storing the second check data. It should be noted that memory blocks in the second memory region includes faulty memory blocks and qualified memory blocks (also referred to as target second memory blocks), where the fourth physical address points to a target second memory block in the second memory region. The target second memory block may be an idle second memory block in the second memory region or an occupied second memory block satisfying a capacity, the occupied second memory block indicates that the check data is not fully written and the remaining storage capacity is greater than or equal to the data amount size of the check data.

At operation S108, a fourth writing instruction including the fourth physical address may be sent, and the operation ends.

FIG. 17B is a second flowchart of a method of operating a memory system according to an implementation of the present application. Referring to FIG. 17B, the method may include operations S110-S118

As shown in FIG. 17B, at operation S110, whether the number of bad blocks in the die is greater than a preset threshold may be determined. If the determination result of S110 is “no”, the operation ends.

If the determination result of S110 is “yes”, the operations may proceed to S111.

A operation S111, whether the faulty die is located in the first memory region may be determined; in other words, whether the die in which the user data is located is faulty may be determined, or the die in which the check data is located is faulty may be determined.

If the determination result in S111 is “yes”, indicating that the die in which the user data is located is faulty, the operations may proceed to S112.

The dies in the first memory region includes the qualified dies and the faulty dies. At operation S112, partial user data stored in the faulty die in the first memory region may be migrated to the qualified die in the first memory region.

At operation S113, a redundant array coding operation may be reperformed on the partial user data migrated to the qualified dies in the first memory region and the remaining user data that is not migrated in the qualified dies in the first memory region to generate first check data.

At operation S114, a third physical address may be for storing the first check data.

At operation S115, a third writing instruction including the third physical address may be sent to the memory device, and the operation ends.

If the determination result of S111 is “no,” indicating that the die in which the check data is located is faulty, at operation S116, the redundant array coding operation may be reperformed on the user data stored in the first memory region to generate the second check data.

At operation S117, a fourth physical address for storing the second check data may be allocated. It should be noted that the dies in the second memory region includes qualified dies and faulty dies, where the fourth physical address points to qualified dies in the second memory region.

At operation S118, a fourth writing instruction including the fourth physical address may be sent, and the operation ends.

According to a third aspect, the implementations of the present application further provides a memory controller, the memory controller is coupled to the memory device, and the memory device includes a plurality of memory regions. The memory controller includes a cache, and a processor. The processor is configured to perform a redundant array coding operation on the received user data to generate check data; the processor is configured to allocate a first physical address of the user data, where the first physical address points to a first memory region in the plurality of memory regions; the processor is configured to allocate a second physical address for storing the check data, and record a second physical address, where the second physical address points to a second memory region in the plurality of memory regions that is different from the first memory region; the processor is configured to send a first writing instruction including the first physical address to the memory device, where the first writing instruction indicates to write the user data to the first memory region; and the processor is configured to send a second writing instruction that includes the second physical address and is different from the first writing instruction to the memory device, where the second writing instruction indicates to write the check data to the second memory region.

The memory controller herein may be the memory controller 104 as shown in FIGS. 1, 2, 3, and 6. The processor herein may be construed as the processor 1043 shown in FIG. 6, and the cache herein may be construed as the cache 1048 shown in FIG. 6. Further details about the memory controller are described in detail in the foregoing, and details are not described herein again for brevity.

In some implementations, the first memory region includes a plurality of first dies, and the first die includes a plurality of first memory blocks. where a plurality of first memory blocks in different first dies form a superblock; and the processor is configured to allocate a first physical address based on the plurality of managed superblocks, where the first physical address points to a target superblock in the plurality of superblocks.

In some implementations, the second memory region includes at least one second die, and the second die includes a plurality of second memory blocks; and the processor is further configured to allocate the second physical address based on the plurality of managed second memory blocks, where the second physical address points to a target second memory block in the plurality of second memory blocks.

In some implementations, the processor is configured to manage a plurality of the superblocks and a plurality of the second memory blocks.

In some implementations, as shown in FIG. 6, the memory controller 104 includes a first management module 1044 and a second management module 1045. The first management module 1044 is configured to manage a plurality of superblocks, and the second management module 1045 is configured to manage a plurality of second memory blocks.

In some implementations, the processor is further configured to obtain first metadata related to the user data from the memory device, where the first metadata includes index information related to the check data; the processor is further configured to retrieve a mapping table based on the index information; and the processor is further configured to determine the second physical address for storing the check data; where the mapping table includes a mapping relationship between the index information and the second physical address.

In some implementations, as shown in FIG. 6, the memory controller 104 includes a lookup-table module 1046, where the lookup-table module 1046 is configured to: retrieve the mapping table based on the index information to determine a target entry in the plurality of entries.

In some implementations, the mapping table includes a plurality of entries, and one entry records the second physical address corresponding to one piece of index information; the processor is configured to retrieve the mapping table based on the index information to determine a target entry in the plurality of entries; and the processor is configured to determine the second physical address for storing the check data based on the target entry.

In some implementations, the superblock includes at least one stripe, the first physical address points to a target stripe in a plurality of stripes of the target superblock, and the target stripe is configured to store the user data; the processor is configured to determine a corresponding second identifier in the index information based on a first identifier in the index information, where the first identifier is configured to indicate a position of the target stripe, and the second identifier is configured to indicate a position of the target entry; and the processor is configured to obtain the target entry based on the second identifier.

In some implementations, the processor is configured to allocate a blank entry of the plurality of entries and record the second physical address into the blank entry.

In some implementations, the processor is further configured to obtain second metadata related to the check data from the memory device, where the second metadata includes address information related to the user data; the processor is configured to determine that an error occurs in the second physical address recorded in the target entry based on the address information in the second metadata does not match the first physical address; and the processor is configured to reconstruct the target entry based on an error that occurs in the second physical address recorded in the target entry.

In some implementations, the processor is further configured to determine that the second physical address recorded in the target entry is correct based on the address information in the second metadata matches the first physical address.

In some implementations, the address information in the second metadata includes a start bit for storing a physical address of the user data and an end bit for storing a physical address of the user data.

In some implementations, the memory cells of the first memory region and the memory cells of the second memory region are respectively configured in different storage modes.

In some implementations, the memory cell in the first memory region is configured to store M-bit data, and the memory cell in the second memory region is configured to store N-bit data, where both M and N are integers greater than 1, and N is less than M.

In some implementations, the processor is further configured to obtain user data stored in a first memory region from a memory device; the processor is further configured to send a reading instruction including a second physical address to the memory device based on an error-correcting code check performed on the obtained user data fails, where the reading instruction indicates to read the check data stored in the second memory region; and the processor is further configured to perform a redundant array check on the user data by using the read check data.

According to a fourth aspect, an implementation of the present application further provides a method of operating a memory system.

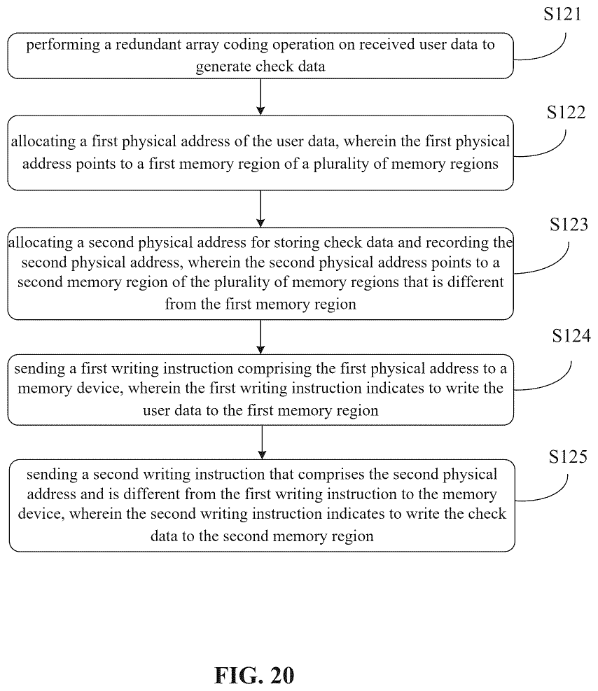

FIG. 20 is a third flowchart of a method of operating a memory system according to an implementation of the present application. As shown in FIG. 20, the method may include operations S121-S125.

Referring to FIG. 20, at operation S121, a redundant array coding operation may be performed on received user data to generate check data.

At operation S122, a first physical address of the user data may be allocated, where the first physical address points to a first memory region in a plurality of memory regions of the memory device.

At operation S123, a second physical address may be allocated for storing check data and recording the second physical address, where the second physical address points to a second memory region of the plurality of memory regions that is different from the first memory region.

At operation S124, a first writing instruction including the first physical address may be sent to a memory device in the memory system, where the first writing instruction indicates to write the user data to the first memory region.

At operation S125, a second physical address and a second writing instruction that includes the second physical address and is different from the first writing instruction may be sent to the memory device, where the second writing instruction indicates to write the check data to the second memory region.

In some implementations, the first memory region includes a plurality of first dies, and the first die includes a plurality of first memory blocks, where a plurality of first memory blocks in different first dies form a superblock; the allocating a first physical address for storing the user data includes allocating the first physical address based on a plurality of managed superblocks, where the first physical address points to a target superblock in a plurality of superblocks.

In some implementations, the second memory region includes at least one second die, and the second die includes a plurality of second memory blocks; and the allocating a second physical address for storing the check data includes allocating the second physical address based on a plurality of managed second memory blocks, where the second physical address points to a target second memory block in a plurality of second memory blocks.

In some implementations, the method further includes obtaining first metadata related to the user data from the memory device, where the first metadata includes index information related to the check data; and the method further includes retrieving a mapping table based on the index information to determine the second physical address for storing the check data; where the mapping table includes a mapping relationship between the index information and the second physical address.

In some implementations, the mapping table includes a plurality of entries, and one entry records the second physical address corresponding to one piece of the index information; and the retrieving a mapping table based on the index information to determine the second physical address for storing the check data includes retrieving the mapping table based on the index information to determine a target entry in the plurality of entries; and determining the second physical address for storing the check data based on the target entry.

In some implementations, the superblock includes at least one stripe, the first physical address points to a target stripe in a plurality of stripes of the target superblock, and the target stripe is configured to store the user data; the retrieving the mapping table based on the index information to determine a target entry in the plurality of entries includes determining a corresponding second identifier in the index information based on a first identifier in the index information, where the first identifier is configured to indicate a position of the target stripe, and the second identifier is configured to indicate a position of the target entry; and obtaining the target entry based on the second identifier.

In some implementations, the recording the second physical address includes allocating a blank entry in the plurality of entries, and recording the second physical address into the blank entry.

In some implementations, the method further includes obtaining second metadata related to the check data from the memory device, where the second metadata includes address information related to the user data; the method further includes determining that an error occurs in the second physical address recorded in the target entry based on the address information in the second metadata does not match the first physical address; and the method further includes reconstructing the target entry based on an error that occurs in the second physical address recorded in the target entry.

In some implementations, the method further includes determining that the second physical address recorded in the target entry is correct based on the address information in the second metadata matches the first physical address.

In some implementations, the address information in the second metadata includes a start bit for storing a physical address of the user data and an end bit for storing a physical address of the user data.

In some implementations, the memory cell of the first memory region is configured to store M-bit data, and the memory cell of the second memory region is configured to store N-bit data, where both M and N are integers greater than 1, and N is less than M.

In some implementations, the method further includes obtaining user data stored in the first memory region from a memory device; the method further includes sending a reading instruction including a second physical address to the memory device based on an error-correcting code check performed on the obtained user data fails, where the reading instruction indicates to read the check data stored in the second memory region; and the method further includes performing a redundant array check on the user data by using the read check data.

The operation method mentioned in the foregoing implementations has been described in detail in the foregoing implementations of the memory system, and details are not described herein again for brevity.

The process of writing the user data and the check data to the first memory region and the second memory region respectively, is further described in conjunction with FIGS. 13-16 and 21A and 21B.

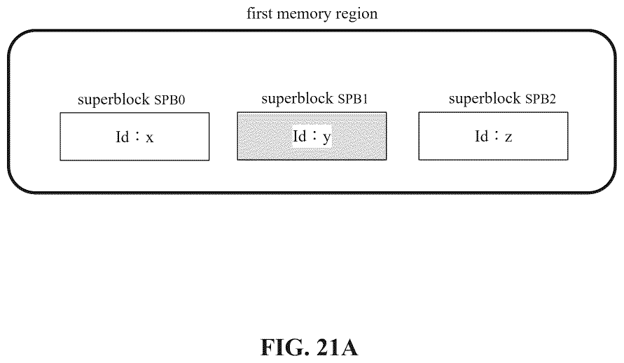

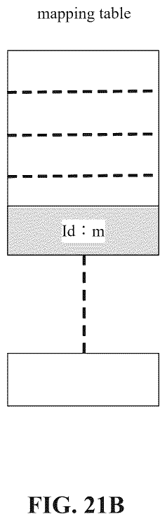

In some implementations, performing the redundant array coding operation on the received user data, after generating the check data, allocating the first physical address for storing the user data, as shown in FIG. 21A, may include allocating a new superblock SPB1 for the user data in the first memory region, and the corresponding Id is y.

Allocating a blank entry from the mapping table for the newly allocated superblock SPB1, and the blank entry shown in FIG. 21B is an entry corresponding to Id: m.

Allocating the second physical address to the check data in the second memory region, and recording the second physical address into the blank entry of the mapping table. For example, as shown in FIG. 16, the information related to the second physical address recorded in the entry of the mapping table includes at least: a Die ID and a Block ID.

In some implementations, when the check data is stored in the superblock including the same numbered second memory blocks of the second memory region shown in FIG. 14, the information related to the second physical address recorded in the entry of the mapping table includes at least: a Die ID, a Raid stripe start ID, a Raid stripe end ID, and a Block ID.

Sending a first writing instruction, writing user data to the superblock SPB1, and updating the first metadata.

Sending a second writing instruction, writing the check data to the second memory block in the second memory region, and updating the start bit of the physical address for storing the user data and the end bit of the physical address for storing the user data into the second metadata.

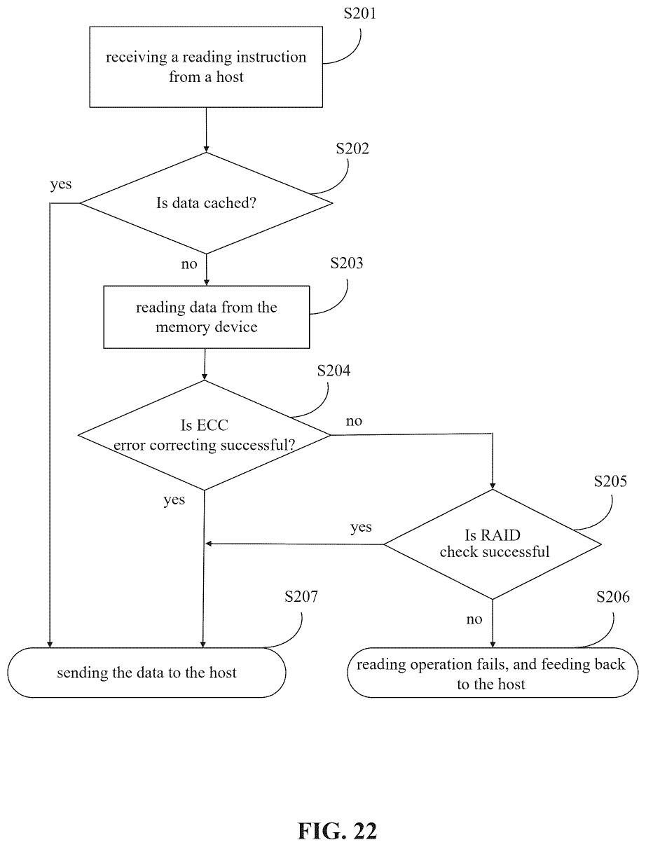

FIG. 22 is a schematic flowchart of a method of data reading process according to an implementation of the present application. As shown in FIG. 22, the method may include operations S201-S207.

Referring to FIG. 22, at operation S201, the memory controller receives a reading instruction from a host.

At operation S202, it is determined whether the data is cached.

If the determination result of S201 is “yes”, then the memory controller obtains data from the cache, and proceeds to operation S207, where it sends the obtained data to the host.

If the determination result of S201 is “no”, the operations may proceed to S203. At operation S203, data is read from the memory device.

In the process of obtaining the target data from the memory, if a reading error occurs, then the error-correcting code engine is configured to perform error correction on the read data.

At operation S204, it is determined whether the ECC error correction is successful.

If the ECC error correction is successful, the decoded correct data is sent to the host.

If the ECC error correction fails, then at operation S205, a RAID check is performed on the error data. If the RAID check at operation S205 succeeds, the operations may proceed to S207, where the data is sent to the host.

If the RAID check fails, the operations may proceed to S206. At operation S206, it is determined that the read operation fails, and information associated with the read operation failure is sent to the host.

For example, as shown in FIG. 14, performing the RAID check includes sending a reading instruction including the second physical address to the memory device to obtain the check data stored in the second memory region based on an ECC error correction performed on the user data in the first memory block 0 of the first die 0 in the obtained stripe Stripe 0 fails; performing the RAID check includes performing the RAID check includes sending a reading instruction including the first physical address to the memory device to obtain other user data stored in the stripe Stripe 0 of the first memory region; and performing the RAID check includes restoring the user data in the first memory block 0 of the first die 0 in the stripe Stripe 0 based on the check data and the other user data stored in the stripe Stripe 0 stored in the first memory region.

It should be noted that the check data, the first check data, and the second check data in the implementations of the present application are configured to perform RAID check in operation S205.

According to a fifth aspect, the implementation of the present application provides a storage medium, where the storage medium stores an executable instruction that, when executed by a processor, implements the operation method according to any one of the foregoing implementations.

In some implementations, the storage medium may be a Ferromagnetic Random Access Memory (FRAM), a Read Only Memory (ROM), a Programmable Read-Only Memory (PROM), an Erasable Programmable Read-Only Memory (EPROM), an Electrically Erasable Programmable Read-Only Memory (EEPROM), a Flash Memory, a magnetic surface memory, an optical disk, or a Compact Disc Read-Only Memory (CD-ROM), or the like; or may be various devices including one or any combination of the foregoing memory devices.

In some implementations, the executable instructions may be written in the form of a program, software, software module, script, or code, written in any form of programming language (including compiled or interpreted languages, or declarative or procedural languages), and it may be deployed in any form, including being deployed as a standalone program or as a module, component, subroutine, or other element suitable for use in a computing environment.

As an example, executable instructions may, but not necessarily, correspond to files in a file system, may be stored in a portion of a file that stores other programs or data, for example, in one or more scripts stored in a Hyper Text Markup Language (HTML) document, in a single file dedicated to the program as discussed, or in multiple collaborative files (e.g., files that store one or more modules, subroutines, or portions of code).

As an example, executable instructions may be deployed for execution on one electronic device, or on multiple electronic devices located at one location, or alternatively on multiple electronic devices distributed at multiple locations and interconnected by a communication network.

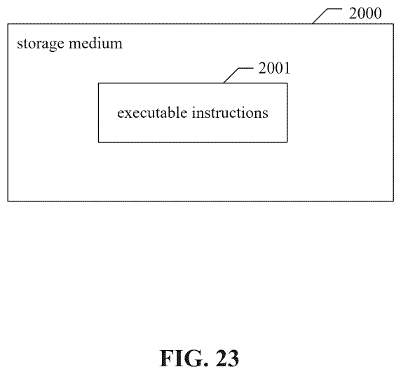

FIG. 23 is a block diagram of a storage medium according to an implementation of the present application. An implementation of the present application provides a storage medium, where the storage medium 2000 stores executable instructions 2001 that, when executed by a processor, implements the operation method of the memory system in the foregoing technical solutions. The operation method includes: performing a redundant array coding operation on received user data to generate check data; allocating a first physical address of the user data; where the first physical address points to a first memory region in a plurality of memory regions of the memory device; allocating a second physical address for storing check data, and recording the second physical address; where the second physical address points to a second memory region of the plurality of memory regions that is different from the first memory region; sending a first writing instruction including the first physical address to the memory device; where the first writing instruction indicates to write the user data to the first memory region; and sending a second writing instruction that includes the second physical address and is different from the first writing instruction to the memory device; where the second writing instruction indicates to write the check data to the second memory region. The features disclosed in the several apparatus implementations provided in the present application may be arbitrarily combined without conflict, to obtain a new apparatus implementation.

The method disclosed in the several method implementations provided in the present application may be arbitrarily combined without conflict, to obtain a new method implementation.

It should be understood that “one implementation” or “an implementation” mentioned throughout the disclosure means that a feature, structure, or characteristic related to the implementation is included in at least one implementation of the present application. Thus, “in one implementation” or “in an implementation” appearing throughout the disclosure does not necessarily refer to the same implementation. Further, these features, structures, or characteristics may be incorporated in one or more implementations in any suitable manner. It should be understood that, in various implementations of the present application, the sequence numbers of the foregoing processes do not mean an order of execution, and the order of execution of each process should be determined by using a function and an intrinsic logic thereof, and should not constitute any limitation on an implementation process of the implementations of the present application. The numbers of the above implementations of the present application are merely for description, and do not represent the advantages or disadvantages of the implementations.

What is claimed is:

1. A memory system, comprising:
a memory controller; and
a memory device coupled to the memory controller, the memory device comprising a plurality of memory regions;
wherein the memory controller is configured to:
perform a redundant array coding operation on user data to generate check data;
allocate a first physical address for storing the user data; wherein the first physical address points to a first memory region of the plurality of memory regions;
allocate a second physical address for storing the check data, and recording the second physical address; wherein the second physical address points to a second memory region of the plurality of memory regions that is different from the first memory region;
send a first writing instruction comprising the first physical address to the memory device, wherein the first writing instruction indicates to write the user data into the first memory region; and
send a second writing instruction that comprises the second physical address and is different from the first writing instruction to the memory device; wherein the second writing instruction indicates to write the check data into the second memory region.

2. The memory system according to claim 1, wherein the first memory region comprises a plurality of first dies, and the first die comprises a plurality of first memory blocks; wherein a plurality of the first memory blocks in different first dies form a superblock; wherein the memory controller is configured to:
allocate the first physical address based on the plurality of managed superblocks, wherein the first physical address points to a target superblock in a plurality of superblocks.

3. The memory system according to claim 2, wherein the second memory region comprises at least one second die, the second die comprises a plurality of second memory blocks; wherein the memory controller is further configured to:
allocate the second physical address based on a plurality of managed second memory blocks, wherein the second physical address points to a target second memory block in the plurality of the second memory blocks.

4. The memory system according to claim 2, wherein the memory controller is further configured to:
obtain a first metadata related to the user data from the memory device, wherein the first metadata comprises index information related to the check data; and
retrieve a mapping table based on the index information to determine the second physical address for storing the check data, wherein the mapping table comprises a mapping relationship between the index information and the second physical address.

5. The memory system according to claim 4, wherein the mapping table comprises a plurality of entries, and one of the entries records the second physical address corresponding to one piece of the index information; and the memory controller is configured to:
retrieve the mapping table based on the index information to determine a target entry in the plurality of entries; and
determine the second physical address for storing the check data based on the target entry.

6. The memory system according to claim 5, wherein the superblock comprises at least one stripe, the first physical address points to a target stripe in a plurality of stripes of the target superblock, and the target stripe is configured to store the user data; wherein the memory controller is configured to:
determine a corresponding second identifier in the index information based on a first identifier in the index information, wherein the first identifier is configured to indicate a position of the target stripe, and the second identifier is configured to indicate a position of the target entry; and
obtain the target entry based on the second identifier.

7. The memory system according to claim 5, wherein the memory controller is further configured to:
obtain second metadata related to the check data from the memory device, wherein the second metadata comprises address information related to the user data;
determine that an error occurs in the second physical address recorded in the target entry based on the address information in the second metadata does not match the first physical address; and
reconstruct the target entry based on an error that occurs in the second physical address recorded in the target entry.

8. The memory system according to claim 1, wherein
a memory cell in the first memory region is configured to store M-bit data;
a memory cell in the second memory region is configured to store N-bit data;
both M and N are integers greater than 1; and
N is less than M.

9. The memory system according to claim 1, wherein the memory controller is further configured to:
obtain the user data stored in the first memory region from the memory device;
send a reading instruction comprising the second physical address to the memory device based on an error-correcting code check performed on the obtained user data fails; wherein the reading instruction indicates to read the check data stored in the second memory region; and
perform a redundant array check on the user data by using the check data read from the second memory region.

10. A memory system, comprising:
a memory controller, and
a memory device coupled to the memory controller, the memory device comprising a plurality of dies divided into a plurality of memory regions;
wherein the memory controller is configured to:
migrate a partial user data stored in a faulty memory block in a first memory region to a target memory block in the first memory region based on at least one faulty memory block exists in a first memory region of the plurality of memory regions;
update a first physical address for storing the user data, based on the partial user data migrated to the target memory block in the first memory region, wherein the first physical address points to the first memory region;
re-performing a redundant array coding operation on the partial user data migrated to the target memory block in the first memory region and remaining user data that is not migrated in the first memory region to generate first check data;
allocate a third physical address for storing the first check data, and record the third physical address; wherein the third physical address points to a second memory region of the plurality of memory regions that is different from the first memory region; and
send a third writing instruction comprising the third physical address to the memory device, wherein the third writing instruction indicates to write the first check data into the second memory region.

11. The memory system according to claim 10, wherein the memory controller is further configured to:
re-perform the redundant array coding operation on the user data stored in the first memory region based on the at least one faulty memory block exists in the second memory region to generate second check data;
allocate a fourth physical address for storing the second check data, and record the fourth physical address; wherein the fourth physical address points to a target memory block in the second memory region; and
send a fourth writing instruction comprising the fourth physical address to the memory device, wherein the fourth writing instruction indicates to write the second check data into a target memory block in the second memory region.

12. The memory system according to claim 11, wherein the first memory region comprises a plurality of first dies, the first die comprises a plurality of first memory blocks; wherein a plurality of first memory blocks in different first dies form a superblock; and
wherein the memory controller is configured to allocate the first physical address based on the plurality of managed superblocks, wherein the first physical address points to a target superblock in a plurality of superblocks.

13. The memory system according to claim 12, wherein the memory controller is further configured to:
obtain a third metadata related to the user data from the memory device, wherein the third metadata comprises index information related to the first check data; and
retrieve a mapping table based on the index information to determine the third physical address for storing the first check data; wherein the mapping table comprises a mapping relationship between the index information and the third physical address.

14. The memory system according to claim 13, wherein the mapping table comprises a plurality of entries, and one entry records the third physical address corresponding to one piece of the index information; wherein the memory controller is further configured to:
retrieve the mapping table based on the index information to determine a target entry in the plurality of entries; and
determine the third physical address for storing the first check data based on the target entry.

15. The memory system according to claim 14, wherein the memory controller is further configured to:
obtain a fourth metadata related to the first check data from the memory device, wherein the fourth metadata comprises address information related to the user data;
determine that an error occurs in the third physical address recorded in the target entry based on the address information in the fourth metadata does not match the updated first physical address; and
reconstruct the target entry based on an error that occurs in the third physical address recorded in the target entry.

16. The memory system according to claim 10, wherein
a memory cell in the first memory region is configured to store M-bit data;
a memory cell in the second memory region is configured to store N-bit data;
both M and N are integers greater than 1; and
N is less than M.

17. The memory system according to claim 10, wherein the memory controller is further configured to:
obtain the user data stored in the first memory region from the memory device;
send a reading instruction comprising the third physical address to the memory device based on an error-correcting code check performed on the obtained user data fails, wherein the reading instruction indicates to read the first check data stored in the second memory region; and
perform a redundant array check on the user data using the first check data read from the second memory region.

18. A method of operating a memory system, comprising:
performing a redundant array coding operation on user data to generate check data;
allocating a first physical address for storing the user data, wherein the first physical address points to a first memory region of a plurality of memory regions of a memory device in the memory system;
allocating a second physical address for storing the check data, and recording the second physical address; wherein the second physical address points to a second memory region of the plurality of memory regions that is different from the first memory region;
sending a first writing instruction comprising the first physical address to the memory device, wherein the first writing instruction indicates to write the user data into the first memory region; and
sending a second writing instruction that comprises the second physical address and is different from the first writing instruction to the memory device, wherein the second writing instruction indicates to write the check data into the second memory region.

19. The method according to claim 18, wherein the first memory region comprises a plurality of first dies, and the first die comprises a plurality of first memory blocks, wherein a plurality of first memory blocks in different first dies form a superblock, and wherein the allocating a first physical address for storing the user data comprises:
allocating the first physical address based on the plurality of managed superblocks, wherein the first physical address points to a target superblock in a plurality of superblocks.

20. The method according to claim 18, further comprising:
obtaining the user data stored in the first memory region from the memory device;
sending a reading instruction comprising the second physical address to the memory device based on an error-correcting code check performed on the obtained user data fails, wherein the reading instruction indicates to read the check data stored in the second memory region; and
performing a redundant array check on the user data by using the check data read from the second memory region.
